(19) United States
(12) Patent Application Publication
(10) Pub. No.: US 2025/0014963 A1
(43) Pub. Date: Jan. 9, 2025

(54) SEMICONDUCTOR PACKAGE

(71) Applicant: Samsung Electronics Co., Ltd., Suwon-si (KR)

(72) Inventors: Yongkwan Lee, Suwon-si (KR); Kundae Yeom, Suwon-si (KR); Hyeon Hwang, Suwon-si (KR)

(21) Appl. No.: 18/763,599

(22) Filed: Jul. 3, 2024

(30) Foreign Application Priority Data
Jul. 5, 2023 (KR) 10-2023-0087399
Sep. 22, 2023 (KR) 10-2023-0127368

(51) Int. Cl. H01L 23/367; H01L 23/00; H01L 23/31; H01L 25/18

(52) U.S. Cl. CPC H01L 23/3675; H01L 23/3128; H01L 24/16; H01L 24/48; H01L 24/73; H01L 24/32; H01L 25/18; H01L 2224/16225; H01L 2224/32145; H01L 2224/32225; H01L 2224/48145; H01L 2224/48227; H01L 2224/73204; H01L 2224/73265; H01L 2225/06506; H01L 2225/0651; H01L 2225/06562; H01L 2225/06586; H01L 2225/06589; H01L 2924/1815

(57) ABSTRACT

A semiconductor package includes a substrate, a first semiconductor chip on the substrate, a heat-dissipating structure on the first semiconductor chip, an adhesive layer between the first semiconductor chip and the heat-dissipating structure, a second semiconductor chip on the heat-dissipating structure, a molding film on the substrate and covering at least portions of the first semiconductor chip, the heat-dissipating structure, and the second semiconductor chip, and a shield layer on an upper surface and sidewalls of the molding film, wherein the shield layer includes a first portion extending into a first hole and contacting an upper surface of the first semiconductor chip, and the first hole may penetrate the molding film, the heat-dissipating structure, and the adhesive layer.

### CROSS-REFERENCE TO RELATED APPLICATION

This application is based on and claims priority under 35 U.S.C. § 119 to Korean Patent Application Nos. 10-2023-0087399 and 10-2023-0127368, filed on Jul. 5, 2023 and Sep. 22, 2023, respectively, in the Korean Intellectual Property Office, the disclosures of which are incorporated by reference herein in their entireties.

### BACKGROUND

The inventive concept relates to a semiconductor package, and more particularly, a semiconductor package including a heat-dissipation structure and a shield layer.

Semiconductor packages may be implementation of integrated circuit chips in a form suitable for electric devices. Generally, in semiconductor packages, a semiconductor chip is mounted on a printed circuit board (PCB), and a bonding wire or bumps are used for electric connections between the PCB and the semiconductor chip. According to the high rate and high capacity of semiconductor packages, power consumption of semiconductor packages has been increasing. Accordingly, the importance of thermal properties and reliability of semiconductor packages have increased.

### SUMMARY

The inventive concept provides a semiconductor package with improved heat-dissipating characteristics.

The inventive concept provides a semiconductor package with improved electrical properties and reliability.

The inventive concept relates to a semiconductor package. According to an aspect of the inventive concept, there is provided a semiconductor package including a substrate, a first semiconductor chip on the substrate, a heat-dissipating structure on the first semiconductor chip, an adhesive layer between the first semiconductor chip and the heat-dissipating structure, a second semiconductor chip on the heat-dissipating structure, a molding film on the substrate and covering at least portions of the first semiconductor chip, the heat-dissipating structure, and the second semiconductor chip, and a shield layer on an upper surface and sidewalls of the molding film, wherein the shield layer includes a first portion extending into a first hole and contacting an upper surface of the first semiconductor chip, and the first hole penetrates the molding film, the heat-dissipating structure, and the adhesive layer.

According to another aspect of the inventive concept, there is provided a semiconductor package including a substrate, a first semiconductor chip on the substrate and having a first upper surface and a second upper surface, a heat-dissipating structure on the first semiconductor chip, an adhesive layer between the second upper surface of the first semiconductor chip and the heat-dissipating structure, a second semiconductor chip on an upper surface of the heat-dissipating structure, a molding film on the heat-dissipating structure and the second semiconductor chip, and a metal layer on an upper surface and sidewalls of the molding film, and the metal layer includes a first portion extending into a first hole penetrating the molding film, the heat-dissipating structure, and the adhesive layer, the first portion being in direct contact with the first upper surface of the first semiconductor chip, and a second portion extending into a second hole penetrating the molding film, the second portion being in direct contact with the upper surface of the heat-dissipating structure.

According to another aspect of the inventive concept, there is provided a semiconductor including a substrate including a ground pattern, solder ball terminals on a lower surface of the substrate, a first semiconductor chip on an upper surface of the substrate, bumps between the substrate and the first semiconductor chip and contacting the substrate and the first semiconductor chip, a heat-dissipating structure on an upper surface of the first semiconductor chip and having a width that is greater than a width of the first semiconductor chip, an adhesive layer between the first semiconductor chip and the heat-dissipating structure, a second semiconductor chip on the heat-dissipating structure, bonding wires on the second semiconductor chip and electrically connected to the second semiconductor chip and the substrate, a molding film on the upper surface of the substrate and on side surfaces of the first semiconductor chip, the heat-dissipating structure, the second semiconductor chip, and the bonding wires, and a shield layer on an upper surface and sidewalls of the molding film, the shield layer extending onto side surfaces of the substrate and electrically connected to the ground pattern, wherein the shield layer includes a first portion in a first hole penetrating the molding film, the heat-dissipating structure, and the adhesive layer, a second portion in a second hole penetrating the molding film, wherein a first portion of the shield layer may contact the upper surface of the first semiconductor chip, and the second portion of the shield layer may contact an upper surface of the heat-dissipating structure and may be spaced apart from the first semiconductor chip.

### BRIEF DESCRIPTION OF THE DRAWINGS

Example embodiments will be more clearly understood from the following detailed description taken in conjunction with the accompanying drawings in which:

FIG. 1A is a plan view for describing a semiconductor package according to embodiments;

FIG. 1B is a plan view describing the relationship of a substrate, a first semiconductor chip, and a heat-dissipating structure of the semiconductor package shown in FIG. 1A;

FIG. 1C is a cross-sectional view of the semiconductor package shown in FIG. 1A, taken along a line I-I′;

FIG. 1D is a diagram illustrating an enlarged view of a region II of the semiconductor package shown in FIG. 1C;

FIG. 1E is a diagram illustrating an enlarged view of a region III of the semiconductor package shown in FIG. 1C;

FIG. 2A is a diagram for describing heat dissipation of the semiconductor package shown in FIG. 1A;

FIG. 2B is a diagram of an enlarged view of a region IV shown in FIG. 2A;

FIG. 3A is a diagram for describing a first semiconductor chip and a first portion of a shield layer according to embodiments;

FIG. 3B is a diagram for describing a first semiconductor chip and a second portion of a shield layer according to embodiments;

FIG. 4A is a diagram for describing a first semiconductor chip and a first portion of a shield layer according to embodiments;

FIG. 4B is a diagram for describing a first semiconductor chip and a second portion of a shield layer according to embodiments;

FIG. 5 is a plan view of a semiconductor package according to embodiments;

FIG. 6 is a plan view of a semiconductor package according to embodiments;

FIG. 7A is a plan view of a semiconductor package according to embodiments;

FIG. 7B is a cross-sectional view of the semiconductor package of FIG. 7A, taken along a line I-I′;

FIG. 8 is a diagram for describing a semiconductor package according to embodiments;

FIG. 9A is a plan view for describing a semiconductor package according to embodiments;

FIG. 9B is a plan view for describing the electrical connection and arrangement relationship of upper substrate pads, a second semiconductor chip, and a heat-dissipating structure of the semiconductor package shown in FIG. 9A;

FIG. 9C is a cross-sectional view of the semiconductor package shown in FIG. 9A, taken along a line A-A′;

FIG. 10 is a plan view of a semiconductor package according to embodiments;

FIG. 11 is a cross-sectional view of a semiconductor package according to embodiments;

FIG. 12A is a plan view of a semiconductor package according to embodiments;

FIG. 12B is a cross-sectional view of the semiconductor package shown in FIG. 12A, taken along a line A-A′;

FIGS. 13A to 13C are diagrams for describing a process of manufacturing a semiconductor package according to embodiments;

FIGS. 14A to 14C are diagrams for describing a process of manufacturing a semiconductor package according to embodiments; and

FIGS. 15A to 15C are diagrams for describing a process of manufacturing a semiconductor package according to embodiments.

### DETAILED DESCRIPTION

Throughout the present specification, same reference numerals may denote same components. Hereinafter, a semiconductor package and a method of manufacturing the same, according to the inventive concept, will be described.

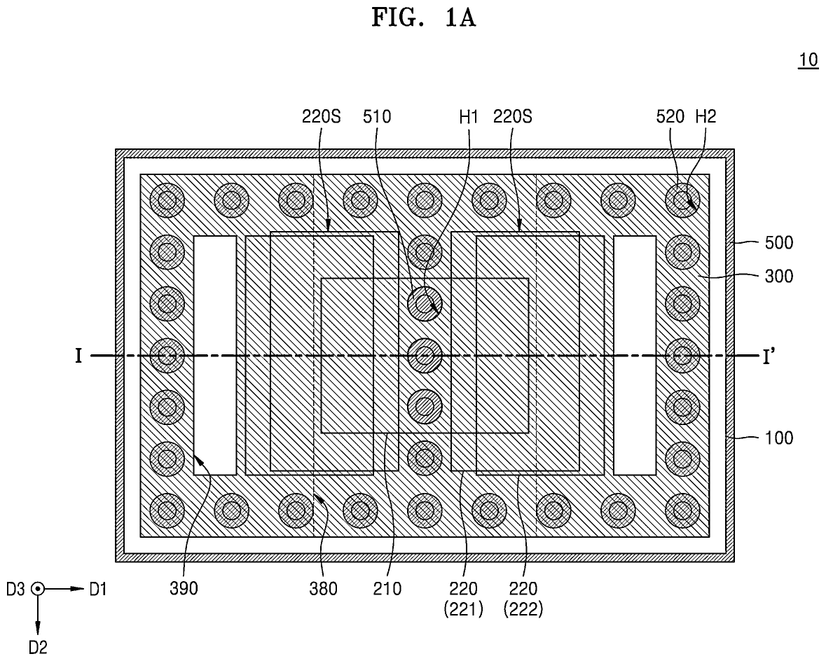

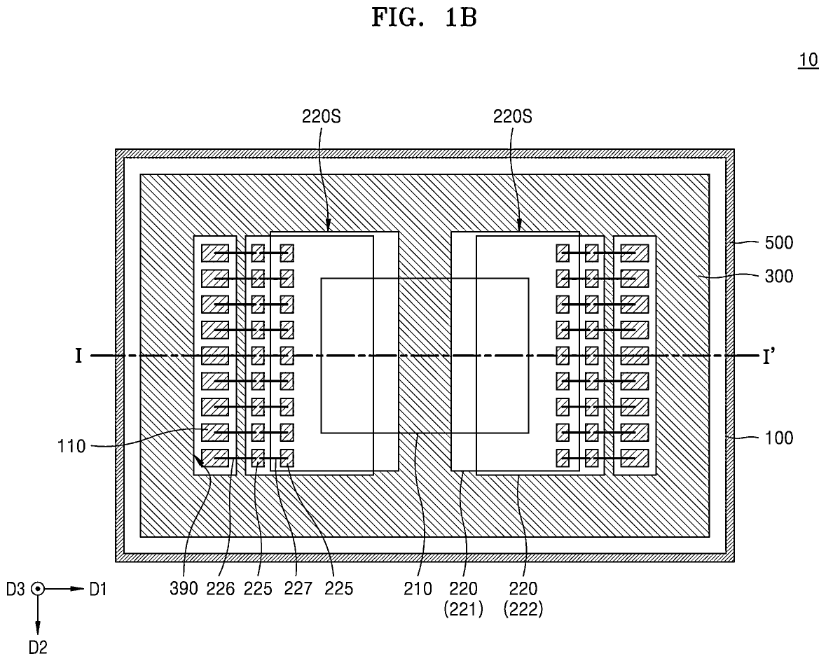

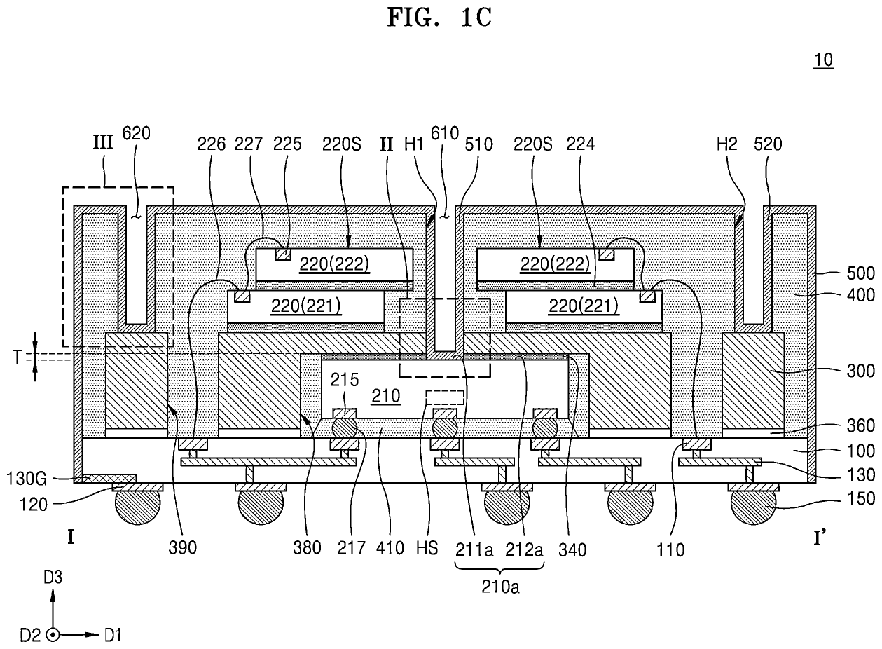

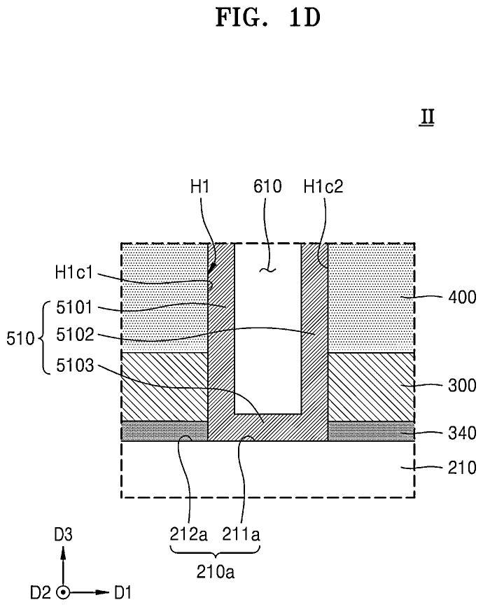

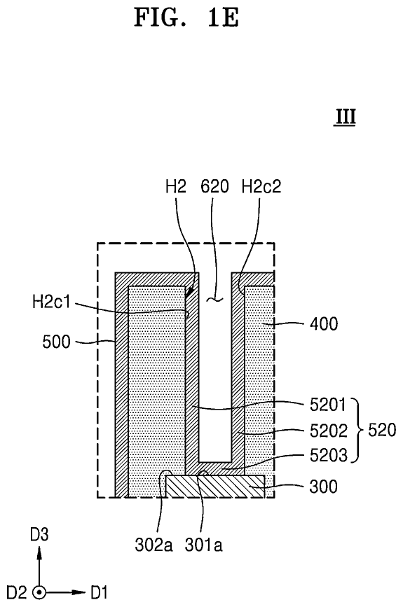

FIG. 1A is a plan view for describing a semiconductor package 10 according to embodiments. FIG. 1B is a plan view describing the relationship of a substrate 100, a first semiconductor chip 210, and a heat-dissipating structure 300 of the semiconductor package 10 shown in FIG. 1A. FIG. 1C, which illustrates a cross-section of the semiconductor package 10 of FIG. 1A, taken along a line I-I′, corresponds to a cross-sectional view of the semiconductor package 10 shown in FIG. 1B, taken along the line I-I′. FIG. 1D is a diagram illustrating an enlarged view of a region II of the semiconductor package 10 shown in FIG. 1C. FIG. 1E is a diagram illustrating an enlarged view of a region III of the semiconductor package 10 shown in FIG. 1C.

Referring to FIGS. 1A, 1B, and IC, the semiconductor package 10 may include the substrate 100, the first semiconductor chip 210, the heat-dissipating structure 300, a second semiconductor chip 220, a molding film 400, and a shield layer 500.

A printed circuit board (PCB) or a redistribution layer may be used as the substrate 100. The substrate 100 may include an insulating base layer, upper substrate pads 110, substrate wirings 130, and a ground pattern 130G. The upper substrate pads 110 may be arranged on an upper surface of the substrate 100. The substrate wirings 130 may be provided in the substrate 100 and electrically connected to the upper substrate pads 110. Electrical connection/contact between two components include direct connection/contact between the two components or indirect connection/contact through another conductive component. Electrical connection to the substrate 100 may indicate electrical connection to at least one of the upper substrate pads 110, the substrate wirings 130, and the ground pattern 130G. The ground pattern 130G may be arranged under a lower surface of the substrate 100. Unlike in the diagram, the ground pattern 130G may be provided in the substrate 100. A surface of the ground pattern 130G may be exposed on a side surface of the substrate 100. The ground pattern 130G, the upper substrate pads 110, and the substrate wirings 130 may include metals such as aluminum, copper, tungsten, and/or titanium. A first direction D1 may be parallel to an upper surface of the substrate 100. A second direction D2 may be parallel to the upper surface of the substrate 100 and may be substantially perpendicular to the first direction D1. A third direction D3 may be substantially perpendicular to the first direction D1 and the second direction D2. The third direction D3 may include a vertical direction.

The semiconductor package 10 may further include solder ball terminals 150. The solder ball terminals 150 may be provided under the lower surface of the substrate 100. The solder ball terminals 150 may include signal solder balls, ground solder balls, and power solder balls. Any one of the solder ball terminals 150 may be provided on a lower surface of the ground pattern 130G and electrically connected to the ground pattern 130G. A solder pad 120 may be further provided between the ground pattern 130G and the any one of the solder ball terminals 150. The any one of the solder ball terminals 150 may include a ground solder ball terminal. Accordingly, a ground voltage may be applied to the ground pattern 130G through the any one of solder ball terminals 150. Unlike in the diagram, the ground pattern 130G may be in direct contact with the any one of the solder ball terminals 150. Other solder ball terminals 150 may be electrically connected to the upper substrate pads 110 through the substrate wirings 130. The solder ball terminals 150 may include solder materials. The solder materials may include, for example, tin, bismuth, lead, silver, or alloys thereof.

The first semiconductor chip 210 may be arranged on the upper surface of the substrate 100. The first semiconductor chip 210 may include a non-memory chip or a logic chip. For example, the first semiconductor chip 210 may include a controller chip. The first semiconductor chip 210 may be mounted on the substrate 100 through a flip-chip method. For example, the semiconductor package 10 may further include bumps 217. The bumps 217 may be between the substrate 100 and the first semiconductor chip 210 and may thus be electrically connected to the upper substrate pads 110 and first chip pads 215 of the first semiconductor chip 210. Accordingly, the first semiconductor chip 210 may be electrically connected to the substrate 100 through the bumps 217. In the present specification, electrical connection of a component to a semiconductor chip may indicate that the component is electrically connected to integrated circuits through chip pads of the semiconductor chip. The bumps 217 may include solder materials. Although not illustrated, the bumps 217 may further include pillar patterns. The pillar patterns may include metal materials that are different from the solder materials.

An upper surface 210a of the first semiconductor chip 210 may include a first upper surface 211a and a second upper surface 212a. The first upper surface 211a of the first semiconductor chip 210 may vertically overlap a heat source HS of the first semiconductor chip 210. The second upper surface 212a of the first semiconductor chip 210 may be connected to the first upper surface 211a.

The semiconductor package 10 may further include an underfill film 410. The underfill film 410 may be provided in a gap region between the substrate 100 and the first semiconductor chip 210, and may cover or surround sidewalls of the bumps 217. The underfill film 410 may include an insulating polymer such as an epoxy polymer.

The heat-dissipating structure 300 may be on the substrate 100 and the first semiconductor chip 210. The heat-dissipating structure 300 may include a heat spreader or a heat sink. The heat-dissipating structure 300 may be provided on the upper surface 210a and above or around sidewalls of the first semiconductor chip 210, and may be spaced apart from the upper surface 210a and the sidewalls of the first semiconductor chip 210. For example, the heat-dissipating structure 300 may be on the second upper surface 212a of the first semiconductor chip 210. The heat-dissipating structure 300 may have a recessed portion 380 in a lower surface thereof. The recessed portion 380 may not penetrate the upper surface of the substrate 100. The first semiconductor chip 210 may be accommodated in the recessed portion 380. For example, the heat-dissipating structure 300 may be arranged such that the first semiconductor chip 210 is provided in the recessed portion 380. As illustrated in FIG. 1A, the recessed portion 380 may extend in a direction parallel to the second direction D2, and may be open toward a sidewall and another sidewall of the heat-dissipating structure 300. The sidewall and the other sidewall of the heat-dissipating structure 300 may face the second direction D2 or a direction opposite to the second direction D2.

A width of the heat-dissipating structure 300 may be greater than a width of the first semiconductor chip 210. A length of the heat-dissipating structure 300 may be greater than a length of the first semiconductor chip 210. The width of the heat-dissipating structure 300 and the width of the first semiconductor chip 210 may be measured in a direction parallel to the first direction D1. The length of the heat-dissipating structure 300 and the length of the first semiconductor chip 210 may be measured in the direction parallel to the second direction D2. Accordingly, the heat-dissipating structure 300 may include an overlapping portion and an overhang portion. The overlapping portion of the heat-dissipating structure 300 may be on the second upper surface 212a of the first semiconductor chip 210 and may overlap the first semiconductor chip 210 in a plan view. The overhang portion of the heat-dissipating structure 300 may be spaced apart from the first semiconductor chip 210 in a plan view. The overhang portion of the heat-dissipating structure 300 may be connected to the overlapping portion without a boundary surface. The overhang portion of the heat-dissipating structure 300 may surround the overlapping portion in a plan view.

The heat-dissipating structure 300 may further include a trench 390. The trench 390 may penetrate an upper surface and a lower surface of the heat-dissipating structure 300. The trench 390 may be spaced apart from the recessed portion 380 in a plan view. Like in the following description, the trench 390 may be provided as a path of first bonding wires 226. The trench 390 may overlap the upper substrate pads 110 in a plan view, and the upper substrate pads 110 may be provided in or on the trench 390. For example, the trench 390 may expose upper surfaces of the upper substrate pads 110. The trench 390 may extend in the second direction D2 in a plan view, but is not limited thereto. The heat-dissipating structure 300 may have a plurality of the trenches 390 spaced apart from one another.

The heat-dissipating structure 300 may have relatively high thermal conductivity. The heat-dissipating structure 300 may include a conductive material, e.g., a metal. For example, the heat-dissipating structure 300 may include copper, steel use stainless (SuS), aluminum, and/or combinations thereof.

The semiconductor package 10 may further include a lower adhesive layer 360. The lower adhesive layer 360 may be provided between the substrate 100 and the heat-dissipating structure 300. The heat-dissipating structure 300 may be attached to the substrate 100 by the lower adhesive layer 360. The lower adhesive layer 360 may include, for example, a thermal interface material (TIM) and/or a polymer. For example, the lower adhesive layer 360 may include a die attach film (DAF).

The semiconductor package 10 may further include an adhesive layer 340. The adhesive layer 340 may be between the first semiconductor chip 210 and the heat-dissipating structure 300. The adhesive layer 340 may stably fix the first semiconductor chip 210 to the heat-dissipating structure 300. Thermal conductivity of the adhesive layer 340 may be less than thermal conductivity of the heat-dissipating structure 300. A thickness T of the adhesive layer 340 may be from about 10 μm to about 50 μm. As the thickness T of the adhesive layer 340 is greater than about 10 μm, the heat-dissipating structure 300 may be stably attached to the first semiconductor chip 210. As the thickness T of the adhesive layer 340 is less than about 50 μm, heat generated in the first semiconductor chip 210 may be transferred to the heat-dissipating structure 300 through the adhesive layer 340. The adhesive layer 340 may include materials that are different from materials of the heat-dissipating structure 300. The adhesive layer 340 may include a TIM, a solder paste material, and/or a polymer. The TIM may include, for example, a polymer and heat-conductive particles. The heat-conductive particles may be distributed in a polymer. The heat-conductive particles may include metals.

Second semiconductor chips 220 may be provided on the upper surface of the heat-dissipating structure 300. The second semiconductor chips 220 may include semiconductor chips that are different from the first semiconductor chip 210. For example, the second semiconductor chips 220 may include NAND flash memory chips. As another example, the second semiconductor chips 220 may include dynamic random-access memory (DRAM), magnetoresistive random-access memory (MRAM), and/or phase change random-access memory (PRAM).

The second semiconductor chips 220 may include second lower semiconductor chips 221 and a second upper semiconductor chips 222. The second semiconductor chips 220 may construct chip stacks 220S. Each of the chip stacks 220S may include the second lower semiconductor chip 221 and the second upper semiconductor chip 222. The chip stacks 220S may be horizontally spaced apart from each other. For example, the chip stacks 220S may be spaced apart from each other in the first direction D1. Each of the chip stacks 220S may be arranged between the trenches 390. Each of the chip stacks 220S may be arranged adjacent the trench 390 corresponding to each of the chip stacks 220S. For example, each of the chip stacks 220S may have a staircase structure or a stepped structure or a cascade structure. Each of the chip stacks 220S may have a staircase structure in which a height thereof increases away from a corresponding trench 390. The number of second semiconductor chips 220 included in the chip stacks 220S is not limited to the illustration and may be variously modified. For example, each of the chip stacks 220S may include three or more second semiconductor chips 220. As another example, the semiconductor package 10 may not include the second upper semiconductor chips 222.

The second semiconductor chips 220 may respectively include second chip pads 225. The second chip pads 225 may be provided on upper surfaces of the second semiconductor chips 220. The second chip pads 225 may be arranged adjacent to corresponding trenches 390 in a plan view. The second chip pads 225 may include metal materials such as copper and/or aluminum.

The first bonding wires 226 may be provided on upper surfaces of the second lower semiconductor chips 221, and first end portions of the first bonding wires 226 may be in contact with the second chip pads 225 of the second lower semiconductor chips 221. As illustrated in FIG. 1B, the first bonding wires 226 may be spaced apart from one another. The first bonding wires 226 may be provided in corresponding trenches 390 and may contact with the upper substrate pads 110 through the trenches 390. For example, second end portions of the first bonding wires 226 may contact the upper substrate pads 110.

When the trenches 390 are omitted, the first bonding wires 226 may be provided on outer sidewalls of the heat-dissipating structure 300. In this case, the width of the heat-dissipating structure 300 may be limited, or the first bonding wires 226 may contact the heat-dissipating structure 300 and cause an electrical short. According to embodiments, as the heat-dissipating structure 300 has the trenches 390, the first bonding wires 226 may easily be in contact with the upper substrate pads 110 through the trenches 390. Accordingly, a length of the first bonding wires 226 decrease, and a length of an electrical path between the second semiconductor chips 220 and the substrate 100 may decrease. The semiconductor package 10 may have improvement in performance. The first bonding wires 226 may be spaced apart from sidewalls of the trenches 390 in the trenches 390. Accordingly, even when the heat-dissipating structure 300 has a relatively great width, the occurrence of an electric short between the first bonding wires 226 and the heat-dissipating structure 300 may be prevented. The first bonding wires 226 may be electrically separate from the heat-dissipating structure 300. In addition, as the heat-dissipating structure 300 has the trench 390, limitation on the width of the heat-dissipating structure 300 may be reduced.

Second bonding wires 227 may be provided on upper surfaces of the second lower semiconductor chips 221 and upper surfaces of the second upper semiconductor chips 222, and may contact with the second chip pads 225 of the second lower semiconductor chips 221 and the second upper semiconductor chips 222. Accordingly, the second upper semiconductor chips 222 may contact with the upper substrate pads 110 through the second bonding wires 227, the second chip pads 225 of the second lower semiconductor chips 221, and the first bonding wires 226. Unlike this, the second bonding wires 227 may be in direct contact with the second chip pads 225 of the second upper semiconductor chips 222 and the upper substrate pads 110. The first bonding wires 226 and the second bonding wires 227 may include a metal, e.g., gold (Au).

The semiconductor package 10 may further include chip adhesion films 224. The chip adhesion films 224 may be respectively provided on lower surfaces of the second semiconductor chips 220. For example, at least one of the chip adhesion films 224 may be provided between the heat-dissipating structure 300 and the second lower semiconductor chips 221 and attach the second lower semiconductor chips 221 to the heat-dissipating structure 300. Another one of the chip adhesion films 224 may be provided between the second lower semiconductor chip 221 and the second upper semiconductor chip 222, and the second upper semiconductor chip 222 may be attached to the second lower semiconductor chips 221 through the other one of the chip adhesion films 224. The chip adhesion films 224 may include, for example, a DAF.

The molding film 400 may be provided on the upper surface of the substrate 100 to cover the heat-dissipating structure 300, the first semiconductor chip 210, and the second semiconductor chips 220. For example, the molding film 400 may extend into the recessed portion 380 and cover or surround sidewalls of the first semiconductor chip 210 and outer sidewalls of the adhesive layer 340. Unlike in the illustration, the underfill film 410 may be omitted, and the molding film 400 may further extend to the gap region between the substrate 100 and the first semiconductor chip 210 to cover or surround the sidewalls of the bumps 217.

The molding film 400 may be provided in the trenches 390 and may encapsulate the first bonding wires 226. For example, the molding film 400 may fill spaces between the sidewalls of the trenches 390 and the first bonding wires 226. Accordingly, contact between the first bonding wires 226 and the heat-dissipating structure 300 may be prevented. The molding film 400 may cover at least portions of the upper surfaces and may cover or surround the outer sidewalls of the heat-dissipating structure 300. The molding film 400 may cover or surround sidewalls and may cover at least portions of upper surfaces of the second semiconductor chips 220 and encapsulate the second bonding wires 227. The molding film 400 may include an insulating polymer such as an epoxy-based polymer. However, the molding film 400 may include a material that is different from the material of the underfill film 410.

The molding film 400 may include a first hole H1 and second holes H2. The first hole H1 may be provided in the molding film 400 and the adhesive layer 340, and may penetrate the molding film 400 and the adhesive layer 340. The first hole H1 may expose the first semiconductor chip 210. Sidewalls of the first hole H1 may correspond to inner sidewalls of the molding film 400, inner sidewalls of the heat-dissipating structure 300, and inner sidewalls of the adhesive layer 340. A bottom surface of the first hole H1 may correspond to the first upper surface 211a of the first semiconductor chip 210. The first hole H1 may vertically overlap the heat source HS of the first semiconductor chip 210. As illustrated in FIG. 1A, the first hole H1 may have a circular or elliptical shape in a plan view.

The second holes H2 may be provided in the molding film 400. The second holes H2 may penetrate the molding film 400 and expose the upper surface of the heat-dissipating structure 300. The second holes H2 may be provided, for example, on the upper surface of the overhang portion of the heat-dissipating structure 300. The second holes H2 may be spaced apart from the first semiconductor chip 210 in a plan view. As illustrated in FIG. 1A, the second holes H2 may be arranged to surround the second semiconductor chips 220. Each of the second holes H2 may have a circular or elliptical shape in a plan view.

A shield layer 500 may be provided on the molding film 400. The shield layer 500 may be provided on an upper surface of the molding film 400, side surfaces of the molding film 400, and the side surfaces of the substrate 100. The shield layer 500 may cover the exposed surface of the ground pattern 130G and may be electrically connected to the ground pattern 130G. Accordingly, a ground voltage may be applied to the shield layer 500 through the ground pattern 130G. The shield layer 500 may have conductivity and may thus shield the semiconductor package 10 from electromagnetic interference (EMI). EMI indicates that an electromagnetic wave radiated or conducted from an electrical component causes disorder against a reception/transmission function of other electrical components. According to embodiments, the shield layer 500 may absorb electromagnetic waves generated in the first semiconductor chip 210, the second semiconductor chips 220, and other external electronic apparatuses. As the semiconductor package 10 includes the shield layer 500, the semiconductor package 10 may not interrupt operations of other electronic apparatuses and may not be interrupted by operations of other electronic apparatuses. For example, operations of the first semiconductor chip 210 and the second semiconductor chips 220 may be not interrupted by operations of other electronic apparatuses. The other electronic apparatuses may include electronic devices, semiconductor devices, semiconductor packages, transmitters, receivers, passive devices, and/or active devices, but are not limited thereto. As the ground voltage is applied to the shield layer 500, EMI shielding of the shield layer 500 may be further improved.

The shield layer 500 may have relatively high thermal conductivity. For example, the thermal conductivity of the shield layer 500 may be greater than the thermal conductivity of the adhesive layer 340. The shield layer 500 may include a conductive material such as a metal. For example, the shield layer 500 may include copper, steel use stainless (SuS), silver (Ag), and/or combinations thereof. The shield layer 500 may include a single layer or multiple layers. For example, the shield layer 500 may be formed by coating a metal paste on the molding film 400. In this case, the shield layer 500 may include a plurality of metal particles. The metal particles may include Ag, but are not limited thereto.

The shield layer 500 may include a first portion 510 and second portions 520. The first portion 510 of the shield layer 500 may be provided in the first hole H1. For example, the first portion 510 of the shield layer 500 may extend to the sidewalls and the bottom surface of the first hole H1, and may conformally cover the inner sidewalls of the molding film 400, the inner sidewalls of the heat-dissipating structure 300, the inner sidewalls of the adhesive layer 340, and the first upper surface 211a of the first semiconductor chip 210. As the first portion 510 of the shield layer 500 contacts the inner sidewalls of the heat-dissipating structure 300, the ground voltage may be applied to the heat-dissipating structure 300 through the shield layer 500. A planar arrangement of the first portion 510 of the shield layer 500 may correspond to a planar arrangement of the first hole H1.

The second portion 520 of the shield layer 500 may be provided in the second hole H2. For example, the second portion 520 of the shield layer 500 may extend onto sidewalls and a bottom surface of the second hole H2 and may conformally cover the inner sidewalls of the molding film 400 and the upper surface of the heat-dissipating structure 300. As the second portions 520 of the shield layer 500 contact the upper surface of the heat-dissipating structure 300, the ground voltage may be applied to the heat-dissipating structure 300 through the shield layer 500. A planar arrangement of the second portion 520 of the shield layer 500 may correspond to the planar arrangement of the first hole H1.

According to embodiments, as illustrated in FIG. 1A, the first portion 510 and the second portions 520 of the shield layer 500 may be arranged to surround the second semiconductor chips 220 in a plan view. A plurality of the first holes H1 may be provided, and the shield layer 500 may include a plurality of the first portions 510. The plurality of first portions 510 of the shield layer 500 may be arranged between the chip stacks 220S in a plan view. For example, the first portions 510 of the shield layer 500 may be arranged between the second semiconductor chips 220. EMI between the chip stacks 220S may be shielded by the first portions of the shield layer 500. Accordingly, the semiconductor package 10 may have improved reliability and electrical properties. The second portions 520 of the shield layer 500 may be arranged at outer boundaries of the second semiconductor chips 220. Due to the second portions 520 of the shield layer 500, EMI between the second semiconductor chips 220 and other external electronic apparatuses may be further shielded. The reliability and the electrical properties of the semiconductor package 10 may be further improved. Hereinafter, for brevity of explanation, a single first hole H1 and a single first portion 510 of the shield layer 500 will be described.

According to embodiments, the heat-dissipating structure 300 may have conductivity. Due to the first portion 510 and the second portions 520 of the shield layer 500, the ground voltage may be applied to the heat-dissipating structure 300. Accordingly, the heat-dissipating structure 300 may have an electromagnetic wave shield function. The heat-dissipating structure 300 may be provided between the first semiconductor chip 210 and the second semiconductor chips 220. Due to the heat-dissipating structure 300, EMI between the first semiconductor chip 210 and the second semiconductor chips 220 may be shielded. The heat-dissipating structure 300 may be provided on the upper surface 210a and the side surfaces of the first semiconductor chip 210. EMI between the first semiconductor chip 210 and an electronic apparatus may be further shielded. The electronic apparatus may include other electronic apparatuses outside the semiconductor package 10, as well as the second semiconductor chips 220. Accordingly, the operation reliability and electrical properties of the first semiconductor chip 210 may be improved.

A first air path 610 may be provided in the first hole H1 and on the first portion 510 of the shield layer 500. The first air path 610 may be connected to an external space. Second air paths 620 may be provided in the second holes H2 and on the second portions 520 of the shield layer 500. The second air paths 620 may be connected to an external space.

Hereinafter, the first hole H1 and the first portion 510 of the shield layer 500 will be described in further detail with reference to FIG. 1D.

Referring to FIG. 1D in conjunction with FIGS. 1A to IC, the first hole H1 may expose the first upper surface 211a of the first semiconductor chip 210. The first upper surface 211a of the first semiconductor chip 210 may contact the first portion 510 of the shield layer 500. The first upper surface 211a of the first semiconductor chip 210 may be spaced apart from the adhesive layer 340 and the heat-dissipating structure 300. The adhesive layer 340 and the heat-dissipating structure 300 may be arranged on the second upper surface 212a of the first semiconductor chip 210. The second upper surface 212a of the first semiconductor chip 210 may be spaced apart from the shield layer 500 and may be in contact with the adhesive layer 340. The first upper surface 211a of the first semiconductor chip 210 may be provided at a level substantially identical to a level of the second upper surface 212a of the first semiconductor chip 210.

The sidewalls of the first hole H1 may include a first sidewall H1c1 and a second sidewall H1c2 facing each other. The first sidewall H1c1 of the first hole H1 may include a first inner sidewall of the molding film 400, a first inner sidewall of the heat-dissipating structure 300, and a first inner sidewall of the adhesive layer 340. The second sidewall H1c2 of the first hole H1 may include a second inner sidewall of the molding film 400, a second inner sidewall of the heat-dissipating structure 300, and a second inner sidewall of the adhesive layer 340. The first inner sidewall and the second inner sidewall of the molding film 400 may face each other. The first inner sidewall and the second inner sidewall of the heat-dissipating structure 300 may face each other. The first inner sidewall and the second inner sidewall of the adhesive layer 340 may face each other.

The first portion 510 of the shield layer 500 may include a first sidewall or side portion 5101, a second sidewall or side portion 5102, and a first bottom portion 5103. The first bottom portion 5103 of the shield layer 500 may be provided on the first upper surface 211a of the first semiconductor chip 210. The first sidewall portion 5101 of the shield layer 500 may be provided on the first sidewall H1c1 of the first hole H1 and may cover or be on the first inner sidewall of the molding film 400, the first inner sidewall of the heat-dissipating structure 300, and the first inner sidewall of the adhesive layer 340. The first sidewall portion 5101 of the shield layer 500 may be connected to the first bottom portion 5103. The second sidewall portion 5102 of the shield layer 500 may be provided on the second sidewall H1c2 of the first hole H1 and may cover or be on the second inner sidewall of the molding film 400, the second inner sidewall of the heat-dissipating structure 300, and the second inner sidewall of the adhesive layer 340. The second sidewall portion 5102 of the shield layer 500 may be connected to the first bottom portion 5103. An outer sidewall of the second sidewall portion 5102 of the shield layer 500 may be horizontally spaced apart from an outer sidewall of the first sidewall portion 5101. Accordingly, the first air path 610 may be provided between the first sidewall portion 5101 and the second sidewall portion 5102 of the first portion 510 of the shield layer 500. In the present specification, “horizontal” may indicate being parallel to the upper surface of the substrate 100 (see FIG. 1C), the first direction D1, or the second direction D2.

Hereinafter, the second holes H2 and the second portions 520 of the shield layer 500 will be described in further detail with reference to FIG. 1E. In descriptions with reference to FIG. 1E, for brevity, a single second hole H2, a single second portion 520 of the shield layer 500, and a single second air path 620 will be described.

Referring to FIG. 1E in conjunction with FIGS. 1A to IC, the upper surface of the heat-dissipating structure 300 may include a first upper surface 301a and a second upper surface 302a. The second upper surface 302a of the heat-dissipating structure 300 may be connected to the first upper surface 301a. The second hole H2 may expose the first upper surface 301a of the heat-dissipating structure 300. The first upper surface 301a of the heat-dissipating structure 300 may contact the second portion 520 of the shield layer 500. The second upper surface 302a of the heat-dissipating structure 300 may be spaced apart from the shield layer 500 and may contact the molding film 400. The first upper surface 301a of the heat-dissipating structure 300 may be provided at a level substantially identical to a level of the second upper surface 302a, but is not limited thereto.

Sidewalls of each of the second holes H2 may include a first sidewall H2c1 and a second sidewall H2c2 facing each other. The first sidewall H2c1 of the second hole H2 may expose a third inner sidewall of the molding film 400. The second sidewall H2c2 of the second hole H2 may expose a fourth inner sidewall of the molding film 400. The fourth inner sidewall of the molding film 400 may face the third inner sidewall. Each of the second portions 520 of the shield layer 500 may include a first side portion 5201, a second side portion 5202, and a second bottom portion 5203. The second bottom portion 5203 of the shield layer 500 may be provided on the first upper surface 301a of the heat-dissipating structure 300. The first side portion 5201 of the second portion 520 of the shield layer 500 may be provided on the first sidewall H2c1 of the second hole H2 and connected to the second bottom portion 5203. The second side portion 5202 of the second portion 520 of the shield layer 500 may be provided on the second sidewall H2c2 of the second hole H2 and connected to the second bottom portion 5203. The second side portion 5202 of the shield layer 500 may be horizontally spaced apart from the first side portion 5201. Accordingly, the second air path 620 may be provided between corresponding first side portion 5201 and second side portion 5202 of the shield layer 500.

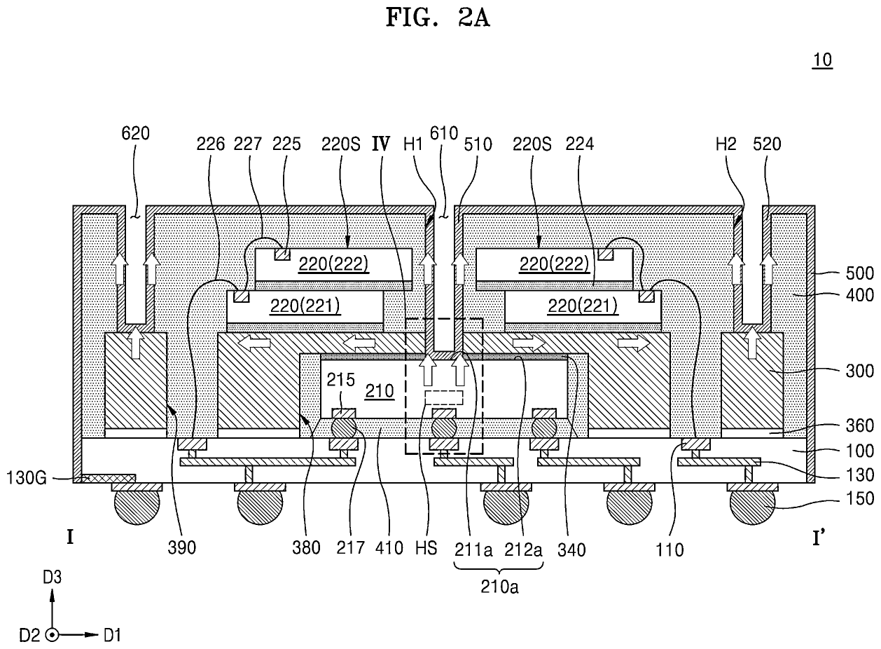

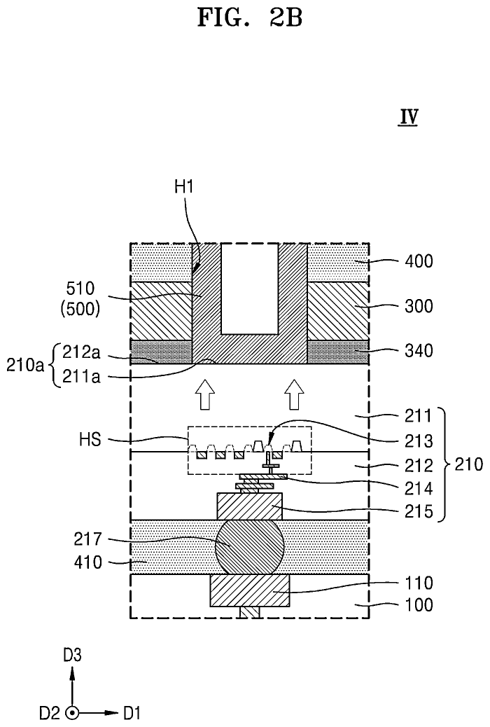

Hereinafter, heat dissipation of the semiconductor package 10 will be described in further detail with reference to FIGS. 2A and 2B.

FIG. 2A is a diagram for describing heat dissipation of the semiconductor package 10 illustrated in FIG. 1A, and corresponds to cross-sections of the semiconductor package 10 respectively taken along line I-I′ in FIG. 1A and line I-I′ in FIG. 1B. FIG. 2B is a diagram of an enlarged view of region IV region in FIG. 2A. Hereinafter, FIGS. 2A and 2B will be described in conjunction with FIGS. 1A to 1E.

Referring to FIGS. 2A and 2B, when the semiconductor package 10 operates, a relatively great amount of heat may be dissipated from the first semiconductor chip 210. For example, a great amount of heat may be dissipated from the heat source HS of the first semiconductor chip 210.

The adhesive layer 340 may have relatively low thermal conductivity. When the first hole H1 and the first portion 510 of the shield layer 500 are omitted, the adhesive layer 340 may cover the first upper surface 211a and the second upper surface 212a of the first semiconductor chip 210. In this case, it may be required that the heat generated in the first semiconductor chip 210 is transferred to the heat-dissipating structure 300 through the adhesive layer 340, and the heat dissipation of the first semiconductor chip 210 may be relatively not smooth. According to embodiments, the first portion 510 of the shield layer 500 may penetrate the molding film 400, the heat-dissipating structure 300, and the adhesive layer 340 and may contact the first upper surface 211a of the first semiconductor chip 210. The thermal conductivity of the shield layer 500 may be greater than the thermal conductivity of the adhesive layer 340. Accordingly, when the semiconductor package 10 operates, the heat generated in the first semiconductor chip 210 may be directly transferred to the first portion 510 of the shield layer 500 without passing through the adhesive layer 340. Accordingly, the heat generated in the first semiconductor chip 210 may be rapidly dissipated, and thus the thermal characteristics of the first semiconductor chip 210 may be improved. As the first portion 510 of the shield layer 500 extends onto the upper surface of the molding film 400, the heat generated in the first semiconductor chip 210 may be more efficiently dissipated along the shield layer 500. The shield layer 500 may be configured to perform a heat dissipation function in addition to EMI shielding function.

The first portion 510 of the shield layer 500 may vertically overlap the heat source HS of the first semiconductor chip 210. As illustrated in FIG. 2B, the heat source HS may include a plurality of integrated circuits 213. For example, the first semiconductor chip 210 may include a semiconductor die 211, the plurality of integrated circuits 213, wirings 214, a lower insulating layer 212, and the first chip pads 215. The plurality of integrated circuits 213 may be provided on a lower surface of the semiconductor die 211. The plurality of integrated circuits 213 may include, for example, transistors. The plurality of integrated circuits 213 may include logic circuits, but are not limited thereto. The lower insulating layer 212 may be provided on the lower surface of the semiconductor die 211 and may cover the plurality of integrated circuits 213. The wirings 214 may be provided in the lower insulating layer 212 and electrically connected to the plurality of integrated circuits 213. The first chip pads 215 may be provided on a lower surface of the first semiconductor chip 210. The first chip pads 215 may be electrically connected to the plurality of integrated circuits 213 through the wirings 214. Density and integration of the plurality of integrated circuits 213 in the heat source HS may be greater than density and integration of the plurality of integrated circuits 213 outside the heat source HS. As the first portion 510 of the shield layer 500 vertically overlaps the heat source HS of the first semiconductor chip 210, the heat of the heat source HS may be more rapidly transferred to the first portion 510 of the shield layer 500. Accordingly, the heat dissipation property of the first semiconductor chip 210 may be further improved. Although not illustrated, the first semiconductor chip 210 may include a plurality of the heat sources HS, and as illustrated in FIG. 1A, the shield layer 500 may include a plurality of the first portions 510. The plurality of first portions 510 of the shield layer 500 may respectively overlap the plurality of heat sources HS in a plan view.

The width and length of the heat-dissipating structure 300 may be greater than the width and length of the first semiconductor chip 210. The heat generated in the first semiconductor chip 210 may be transferred to the heat-dissipating structure 300 through the first portion 510 of the shield layer 500 or the adhesive layer 340. The heat may be horizontally transferred from the inside of the heat-dissipating structure 300 to the outer sidewalls of the heat-dissipating structure 300. For example, the heat may be transferred from the overlapping portion of the heat-dissipating structure 300 to the overhang portion of the heat-dissipating structure 300. The second portions 520 of the shield layer 500 may be provided on the upper surface of the overhang portion of the heat-dissipating structure 300. The heat may be rapidly dissipated through the second portions 520 of the shield layer 500. When the heat dissipation of the first semiconductor chip 210 is concentrated at the first portion 510 of the shield layer 500, a thermal bottleneck phenomenon may occur. According to embodiments, the heat generated in the first semiconductor chip 210 may be dissipated in a scattered manner through the heat-dissipating structure 300 and the second portions 520 of the shield layer 500, as well as the first portion 510 of the shield layer 500. Accordingly, thermal properties of the semiconductor package 10 may be further improved.

According to embodiments, the first air path 610 may be provided in the first hole H1, and the second air paths 620 may be provided in the second holes H2. When the semiconductor package 10 operates, external air may be provided into the first air path 610 and the second air paths 620. Due to increase in an area in which the first portion 510 and the second portions 520 of the shield layer 500 contact the external air, the heat may be more rapidly dissipated toward the external air from the first portion 510 and the second portions 520 of the shield layer 500. The semiconductor package 10 may have further improved heat-dissipation properties.

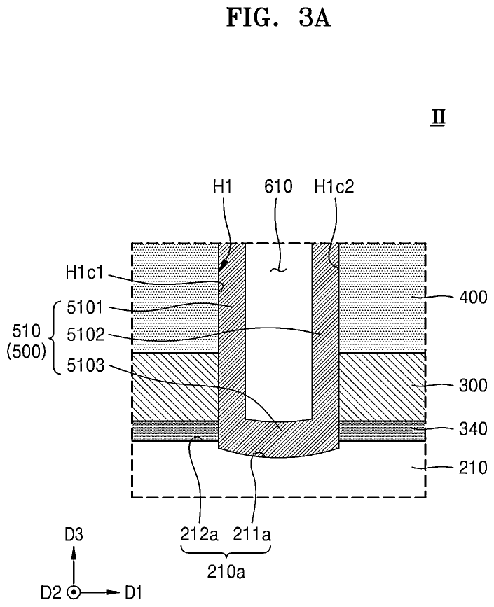

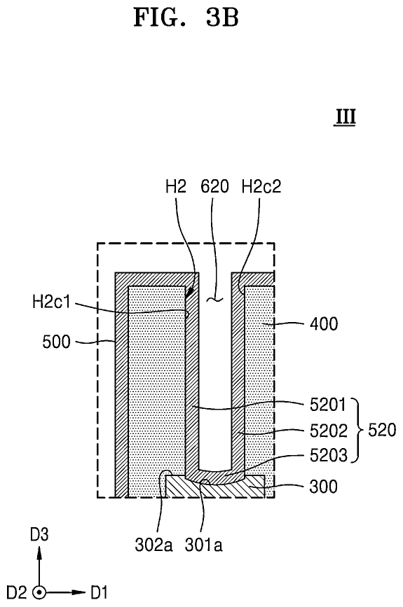

FIG. 3A is a diagram for describing the first semiconductor chip 210 and the first portion 510 of the shield layer 500 according to embodiments, and corresponds to a diagram of an enlarged view of a region II illustrated in FIG. 1C. FIG. 3B is a diagram for describing the first semiconductor chip 210 and the second portion 520 of the shield layer 500, and corresponds to a diagram of an enlarged view of a region III illustrated in FIG. 1C.

Referring to FIG. 3A, the first hole H1 may be recessed into the first semiconductor chip 210. For example, the first upper surface 211a of the first semiconductor chip 210 may be provided at a level lower than a level of the second upper surface 212a. The first upper surface 211a of the first semiconductor chip 210 may protrude downward or be upwardly concave. The second upper surface 212a of the first semiconductor chip 210 may be flat, but is not limited thereto. The first portion 510 of the shield layer 500 may cover the inner sidewalls of the molding film 400, the inner sidewalls of the heat-dissipating structure 300, and the inner sidewalls of the adhesive layer 340, and may conformally cover the first upper surface 211a of the first semiconductor chip 210. The first bottom portion 5103 of the first portion 510 of the shield layer 500 may protrude downward. A lowermost surface of the first portion 510 of the shield layer 500 may be provided at a level lower than a level of the second upper surface 212a of the first semiconductor chip 210. In the present specification, a level of a component may indicate a vertical level measured in a vertical direction.

Referring to FIG. 3B, the second hole H2 may be recessed into the heat-dissipating structure 300. For example, the first upper surface 301a of the heat-dissipating structure 300 may be provided at a level lower than a level of the second upper surface 302a. The first upper surface 301a of the heat-dissipating structure 300 may protrude downward or be upwardly concave. The second upper surface 302a of the heat-dissipating structure 300 may be flat, but is not limited thereto. The second portion 520 of the shield layer 500 may cover the inner sidewalls of the molding film 400 and may conformally cover the first upper surface 301a of the heat-dissipating structure 300. The second bottom portion 5203 of the second portion 520 of the shield layer 500 may protrude downward. A lowermost surface of the second portion 520 of the shield layer 500 may be provided at a level lower than the level of the second upper surface 302a.

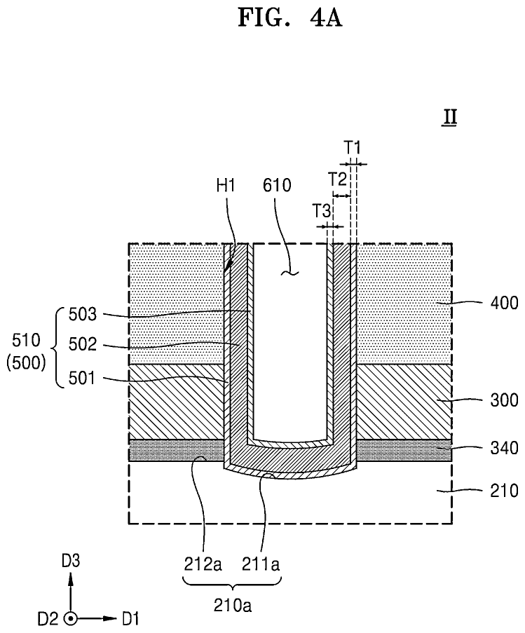

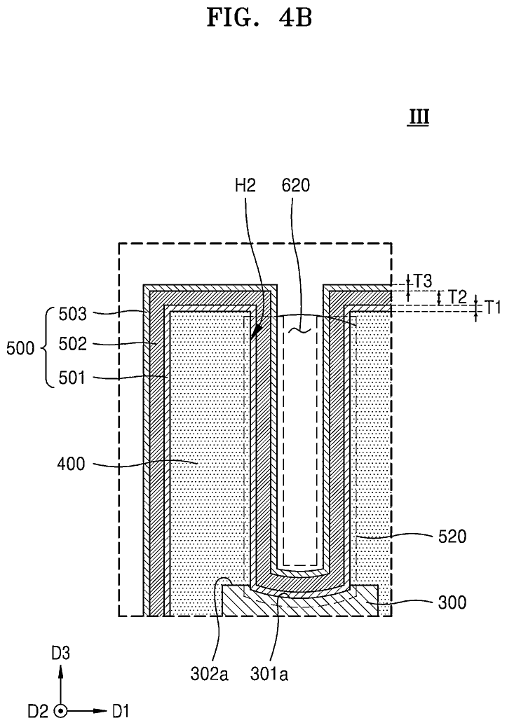

FIG. 4A is a diagram for describing the first semiconductor chip 210 and the first portion 510 of the shield layer 500 according to embodiments, and corresponds to a diagram of an enlarged view of region II illustrated in FIG. 1C. FIG. 4B is a diagram for describing the first semiconductor chip 210 and the second portion 520 of the shield layer 500, and corresponds to a diagram of an enlarged view of region III illustrated in FIG. 1C.

Referring to FIGS. 4A and 4B, the shield layer 500 may include a first metal layer 501, a second metal layer 502, and a third metal layer 503. Accordingly, the first portion 510 and the second portion 520 of the shield layer 500 may each include the first metal layer 501, the second metal layer 502, and the third metal layer 503. The first metal layer 501 may cover the upper surface and sidewalls of the molding film 400. Although not illustrated, the first metal layer 501 may contact the ground pattern 130G (see FIG. 1C) on the side surfaces of the substrate 100. The first metal layer 501 may conformally cover the sidewalls of the first hole H1 and the first upper surface 211a of the first semiconductor chip 210. The first upper surface 211a of the first semiconductor chip 210 may be provided at a level lower than the level of the second upper surface 212a. A lowermost surface of the first metal layer 501 in the first hole H1 may be provided at a level lower than the level of the second upper surface 212a of the first semiconductor chip 210. The first metal layer 501 may conformally cover the sidewalls of the second hole H2 and the first upper surface 301a of the heat-dissipating structure 300. The first upper surface 301a of the heat-dissipating structure 300 may be provided at a level lower than the level of the second upper surface 302a. A lowermost surface of the first metal layer 501 in the second hole H2 may be provided at a level lower than the level of the second upper surface 302a of the heat-dissipating structure 300. The first metal layer 501 may function as a seed layer. The first metal layer 501 may include a first metal. The first metal may include, for example, steel use stainless (SuS). The first metal layer 501 may be formed through a deposition process or a sputtering process. The deposition process may include physical vapor deposition, but is not limited thereto.

The second metal layer 502 may be provided on the first metal layer 501 and may cover the first metal layer 501. The second metal layer 502 may include a second metal. The second metal may be different from the first metal. The second metal may have relatively high thermal conductivity. The thermal conductivity of the second metal layer 502 may be greater than the thermal conductivity of the first metal layer 501 and the thermal conductivity of the third metal layer 503. For example, the second metal may include copper or copper alloy. According to embodiments, a thickness T2 of the second metal layer 502 may be greater than a thickness T1 of the first metal layer 501 and a thickness T3 of the third metal layer 503. Accordingly, the shield layer 500 may have relatively high thermal conductivity and may thus more rapidly dissipate the heat generated in the first semiconductor chip 210. The second metal layer 502 may be formed through a deposition process or a sputtering process. In a deposition process of the second metal layer 502, the first metal layer 501 may function as a seed layer.

The third metal layer 503 may be provided on the second metal layer 502. The third metal layer 503 may prevent oxidation of the second metal layer 502. The third metal layer 503 may include a third metal. The third metal may be different from the second metal. For example, the third metal may include a material that is identical to the material of the first metal. The third metal may include, e.g., steel use stainless (SuS). The third metal layer 503 may be formed through a deposition process or a sputtering process.

Unlike illustrated in FIG. 3A, the first upper surface 211a of the first semiconductor chip 210 may be provided at a level substantially identical to the level of the second upper surface 212a. The first upper surface 301a of the heat-dissipating structure 300 may be provided at a level substantially identical to a level of the second upper surface 302a.

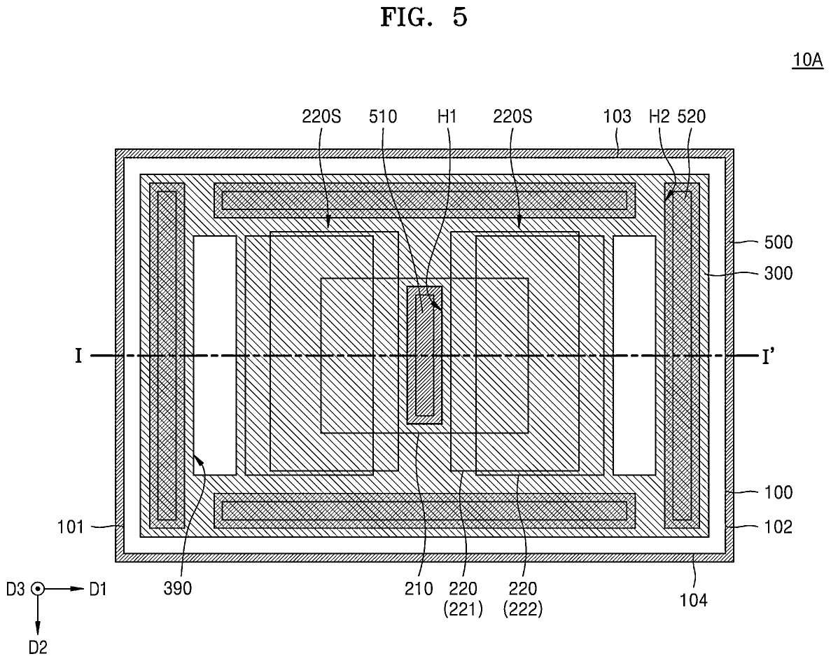

FIG. 5 is a plan view of a semiconductor package 10A according to embodiments. The cross-section taken along line I-I″ in FIG. 5 may be substantially identical to the cross-section shown in FIG. 1C. Hereinafter, FIG. 5 will be described in conjunction with FIG. 1C.

Referring to FIG. 5, the semiconductor package 10A may include the substrate 100, the first semiconductor chip 210, the heat-dissipating structure 300, a second semiconductor chip 220, the molding film 400 (see FIG. 1C), and the shield layer 500. The first hole H1 may be provided between the chip stacks 220S and may extend in the second direction D2 in a plan view. For example, the first hole H1 may have a bar shape or a rectangular shape extending in the second direction D2. As another example, the first hole H1 may have a square shape or a rectangular shape rounded at corners.

In a plan view, each of the second holes H2 may have a bar shape, a square shape such as a rectangular shape, or a square shape or a rectangular shape rounded at corners.

In a plan view, the second holes H2 may be provided between the second semiconductor chips 220 and the side surfaces of the substrate 100. In a plan view, the second holes H2 may be respectively provided on a first region, a second region, a third region, and a fourth region of the substrate 100. For example, the substrate 100 may have a first side surface 101, a second side surface 102, a third side surface 103, and a fourth side surface 104. The second side surface 102 of the substrate 100 may face the first side surface 101. The third side surface 103 of the substrate 100 may be adjacent to the first side surface 101 and the second side surface 102. The fourth side surface 104 of the substrate 100 may face the third side surface 103. The first region of the substrate 100 may be provided between the first side surface 101 of the substrate 100 and the second semiconductor chips 220 adjacent to the first side surface 101. The second region of the substrate 100 may be provided between the second side surface 102 of the substrate 100 and the second semiconductor chips 220 adjacent to the second side surface 102. The third region of the substrate 100 may be provided between the third side surface 103 of the substrate 100 and the second semiconductor chips 220. The fourth region of the substrate 100 may be provided between the fourth side surface 104 of the substrate 100 and the second semiconductor chips 220. Some of the second holes H2 may be provided on the first and second regions of the substrate 100 and may extend in the second direction D2. Others of the second holes H2 may extend in the first direction D1 on the third and fourth regions of the substrate 100. Planar shapes of the first hole H1 and the second holes H2 may be variously modified.

A planar shape of the first portion 510 of the shield layer 500 may correspond to the planar shape of the first hole H1, and a planar shape of the second portions 520 of the shield layer 500 may correspond to the planar shape of the second holes H2.

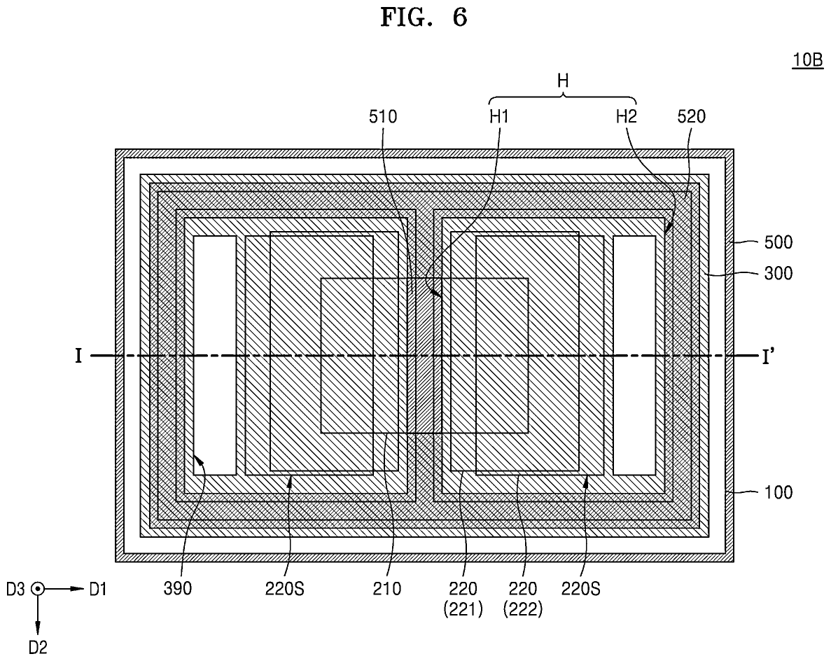

FIG. 6 is a plan view of a semiconductor package 10B according to embodiments. The cross-section taken along line I-I′ line in FIG. 6 may be substantially identical to the cross-section shown in FIG. 1C. Hereinafter, FIG. 6 will be described in conjunction with FIG. 1C.

Referring to FIG. 6, the semiconductor package 10B may include the substrate 100, the first semiconductor chip 210, the heat-dissipating structure 300, the second semiconductor chip 220, the molding film 400 (shown in FIG. 1C), and the shield layer 500.

The second hole H2 may be provided in a singularity or continuously. The first hole H1 and the second hole H2 may be connected to each other to form a single hole H. The single hole H may surround the second semiconductor chips 220 and may include a trench or a groove. For example, in a plan view, the first hole H1 may be provided between the second semiconductor chips 220. End portions of the first hole H1 may be connected to the second hole H2. The second hole H2 may have an outer sidewall and an inner sidewall facing each other. In a plan view, the outer sidewall of the second hole H2 may have a square shape or a rectangular shape or a square shape or a rectangular shape rounded at corners. The second hole H2 may extend between or around the second semiconductor chips 220 and may be connected to the first hole H1.

The second portions 520 of the shield layer 500 may be connected to the first portion 510.

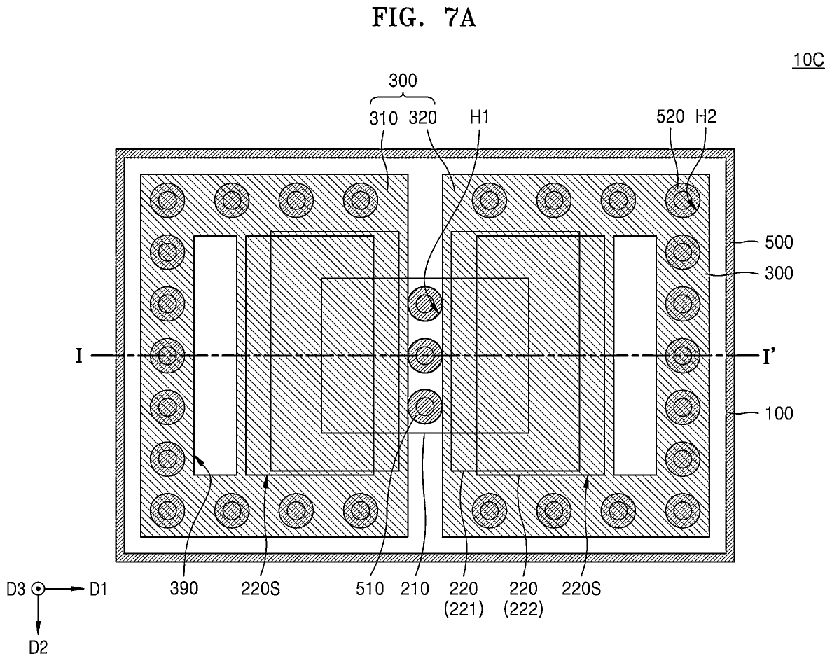

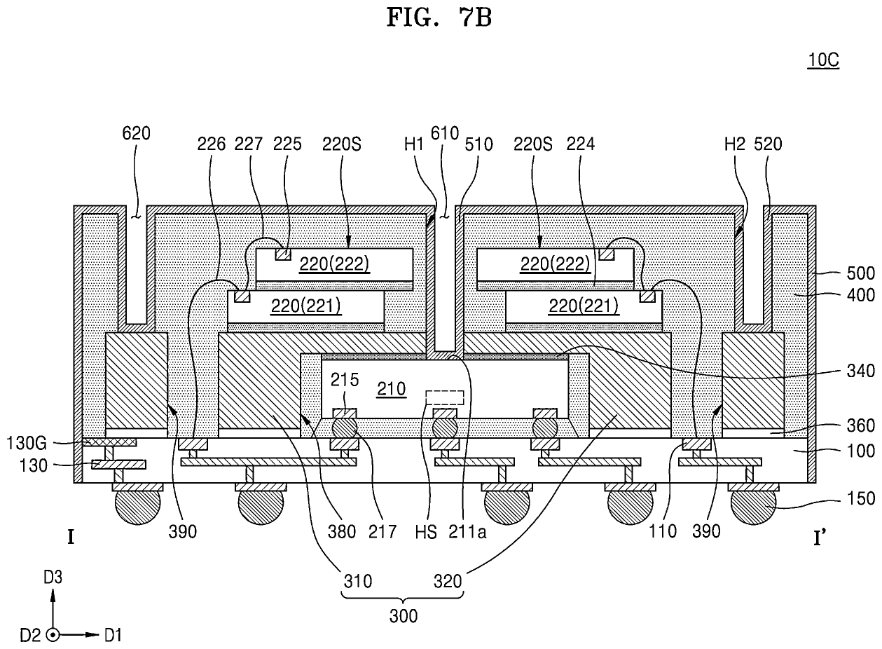

FIG. 7A is a plan view of a semiconductor package 10C according to embodiments; FIG. 7B is a cross-sectional view of the semiconductor package 10C of FIG. 7A, taken along a line I-I′. Hereinafter, same descriptions may be omitted in the interest of brevity.

Referring to FIGS. 7A and 7B, the semiconductor package 10C may include the substrate 100, the first semiconductor chip 210, the adhesive layer 340, the heat-dissipating structure 300, the second semiconductor chip 220, the molding film 400, and the shield layer 500. The substrate 100, the first semiconductor chip 210, the heat-dissipating structure 300, the second semiconductor chip 220, the molding film 400, and the shield layer 500 may be substantially identical to the descriptions provided above.

However, the heat-dissipating structure 300 may include a first heat-dissipating structure 310 and a second heat-dissipating structure 320 horizontally spaced apart from each other. The first hole H1 may be provided between the first heat-dissipating structure 310 and the second heat-dissipating structure 320 and may expose the first upper surface 211a of the first semiconductor chip 210. The first hole H1 may further expose a sidewall of the first heat-dissipating structure 310 and a sidewall of the second heat-dissipating structure 320. As the heat-dissipating structure 300 includes the first heat-dissipating structure 310 and the second heat-dissipating structure 320, in a process of forming the first hole H1, a process of removing a portion of the heat-dissipating structure 300 may be omitted. The first portion 510 of the shield layer 500 may contact the sidewall of the first heat-dissipating structure 310 and the sidewall of the second heat-dissipating structure 320.

The ground pattern 130G may be provided on the upper surface of the substrate 100 and may contact corresponding solder ball terminals 150 through the substrate wirings 130. The ground pattern 130G may be electrically separate from the upper substrate pads 110. The ground pattern 130G and the upper substrate pads 110 may be manufactured in a single same process. The surface of the ground pattern 130G may be exposed on the side surface of the substrate 100 and may contact the shield layer 500. Unlike in the illustration, the ground pattern 130G may be provided on the lower surface of the substrate 100.

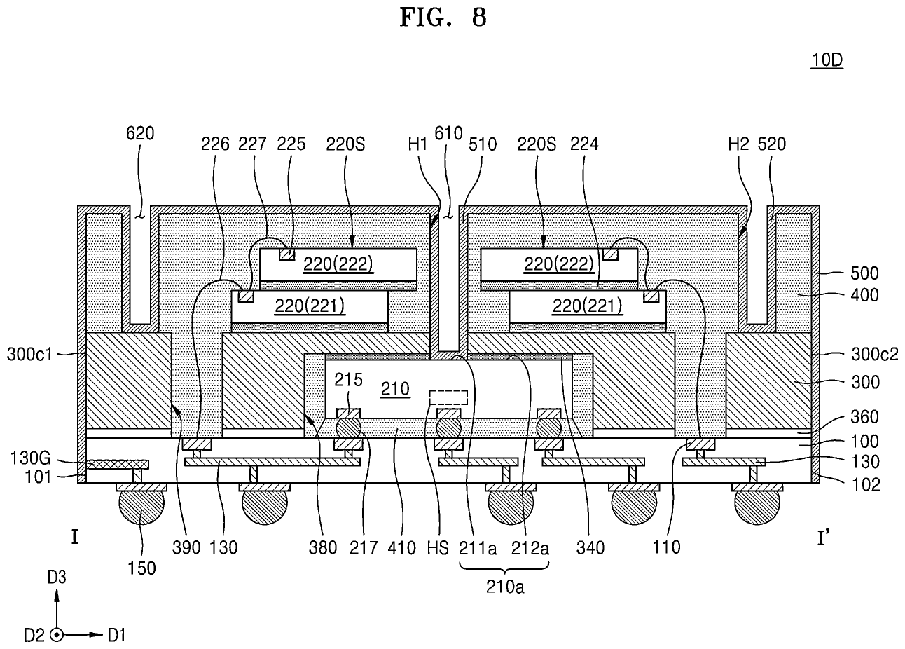

FIG. 8 is a diagram for describing a semiconductor package 10D according to embodiments, and corresponds to a cross-sectional view taken along a I-I′ line in FIG. 1A.

Referring to FIG. 8, the semiconductor package 10D may include the substrate 100, the first semiconductor chip 210, the adhesive layer 340, the heat-dissipating structure 300, the second semiconductor chip 220, the molding film 400, and the shield layer 500. The heat-dissipating structure 300 may have the first outer sidewall 300c1 and the second outer sidewall 300c2 facing each other. Unlike in FIGS. 1A to IC, the first outer sidewall 300c1 of the heat-dissipating structure 300 may be vertically aligned or coplanar with the first side surface 101 of the substrate 100. The second outer sidewall 300c2 of the heat-dissipating structure 300 may be vertically aligned or coplanar with the second side surface 102 of the substrate 100. The molding film 400 may be not provided on the first outer sidewall 300c1 and the second outer sidewall 300c2 of the heat-dissipating structure 300.

The shield layer 500 may cover the upper surface of the molding film 400, the sidewalls of the molding film 400, and the first outer sidewall 300c1 and the second outer sidewall 300c2 of the heat-dissipating structure 300. Therefore, each of the first outer sidewall 300c1 and the second outer sidewall 300c2 of the heat-dissipating structure 300 may be in direct contact with the shield layer 500. The shield layer 500 may further cover the first side surface 101 and the second side surface 102 of the substrate 100. The shield layer 500 may extend into the first hole H1 and the second hole H2.

Unlike in the illustration, the second outer sidewall 300c2 of the heat-dissipating structure 300 may be not vertically aligned with the first side surface 101 of the substrate 100. In this case, the molding film 400 may be further arranged between the second outer sidewall 300c2 of the heat-dissipating structure 300 and the shield layer 500.

The ground pattern 130G may be provided in the substrate 100 and electrically connected to a corresponding solder ball terminal 150. The ground pattern 130G and the substrate wirings 130 may be manufactured in a single same process. A surface of the ground pattern 130G may contact the shield layer 500.

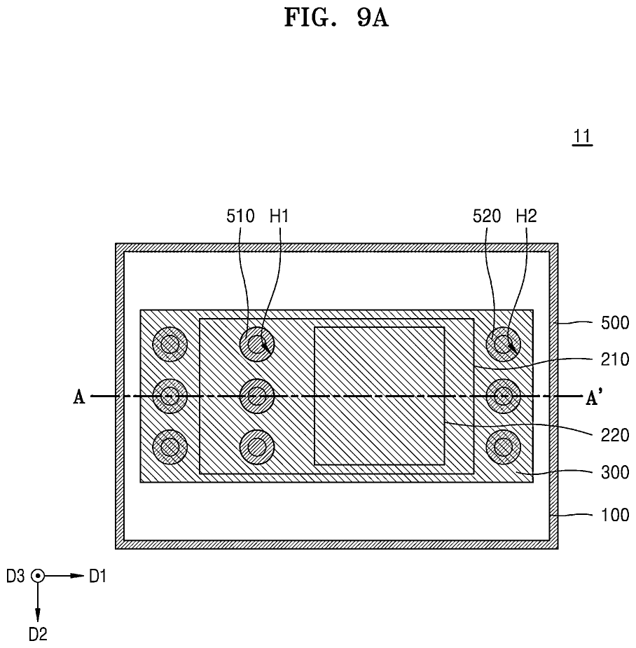

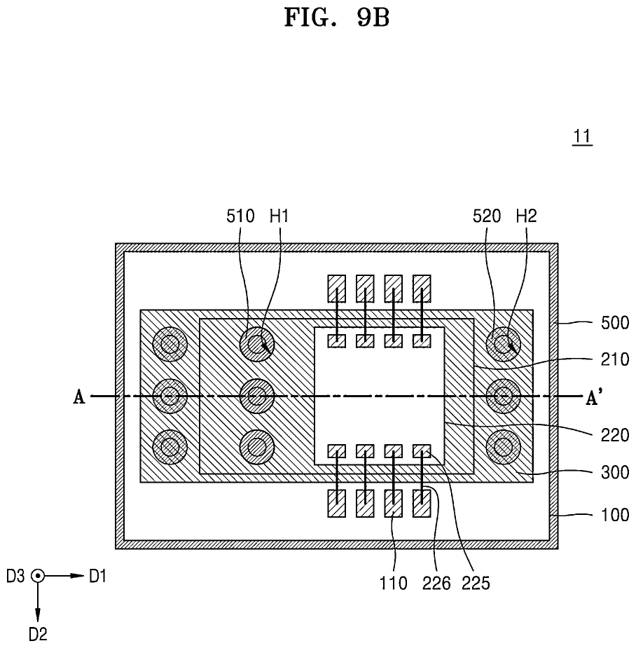

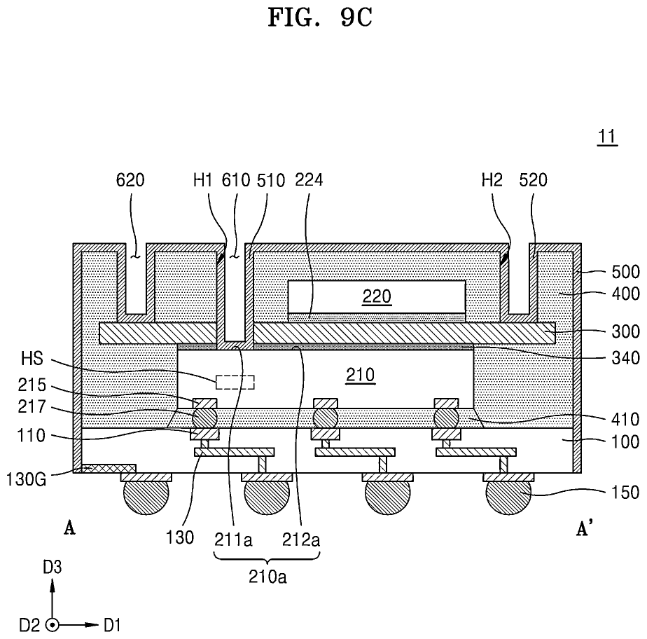

FIG. 9A is a plan view for describing a semiconductor package 11 according to embodiments; FIG. 9B is a plan view for describing the electrical connection and arrangement relationship of upper substrate pads, a second semiconductor chip, and a heat-dissipating structure of the semiconductor package 11 shown in FIG. 9A; FIG. 9C is a cross-sectional view of the semiconductor package 11 shown in FIG. 9A, taken along a line A-A′, and corresponds to a cross-sectional view of the semiconductor package 11 shown in FIG. 9B, taken along the line A-A′. Hereinafter, same descriptions may be omitted in the interest of brevity.

Referring to FIGS. 9A, 9B, and 9C, the semiconductor package 11 may include the substrate 100, the first semiconductor chip 210, the adhesive layer 340, the heat-dissipating structure 300, the second semiconductor chip 220, the molding film 400, and the shield layer 500. The substrate 100, the first semiconductor chip 210, the heat-dissipating structure 300, the second semiconductor chip 220, the molding film 400, and the shield layer 500 may be identical or similar to the descriptions provided above.

The first semiconductor chip 210 may include a communication chip such as a modem chip. As another example, the first semiconductor chip 210 may include an application processor (AP) chip. The semiconductor package 11 may further include the bumps 217 and the underfill film 410.

The heat-dissipating structure 300 may be arranged on the second upper surface 212a of the first semiconductor chip 210. Unlike in FIG. 1C, the heat-dissipating structure 300 may not include the trenches 390 and the recessed portion 380. A lower surface of the heat-dissipating structure 300 may be flat.

The second semiconductor chip 220 may be arranged on an upper surface of the heat-dissipating structure 300. The second semiconductor chip 220 may include a non-volatile memory chip. For example, the second semiconductor chip 220 may include DRAM. As another example, the second semiconductor chip 220 may include SRAM. The second semiconductor chip 220 may be attached to the heat-dissipating structure 300 through the chip adhesion film 224.

As shown in FIG. 9B, the second semiconductor chip 220 may include the second chip pads 225. The second chip pads 225 may be provided on an upper surface of the second semiconductor chip 220. In a plan view, the second chip pads 225 may be adjacent to each of a side surface and another side surface of the second semiconductor chip 220. The side surface and the other side surface of the second semiconductor chip 220 may be parallel to the first direction D1 and may face each other. The second chip pads 225 may construct columns or rows parallel to the first direction D1. The first bonding wires 226 may be arranged on the upper surface of the second semiconductor chip 220 and may contact the second chip pads 225 and the upper substrate pads 110. The first bonding wires 226 may be spaced apart from the heat-dissipating structure 300. Accordingly, an electrical short between the first bonding wires 226 and the heat-dissipating structure 300 may be prevented.

The molding film 400 may be provided on the upper surface of the substrate 100 and may cover at least portions of the first semiconductor chip 210, the second semiconductor chip 220, and the heat-dissipating structure 300. The first hole H1 may penetrate the molding film 400, the heat-dissipating structure 300, and the adhesive layer 340 and expose the first upper surface 211a of the first semiconductor chip 210. The second holes H2 may penetrate the molding film 400 and expose the upper surface of the overhang portion of the heat-dissipating structure 300.

The shield layer 500 may be arranged on the molding film 400. The shield layer 500 may extend on the sidewalls of the substrate 100 and contact the ground pattern 130G. The shield layer 500 may include the first portion 510 and the second portions 520. The first portion 510 of the shield layer 500 may cover the sidewalls and the bottom surface of the first hole H1. The first portion 510 of the shield layer 500 may vertically overlap the heat source HS of the first semiconductor chip 210. The first portion 510 of the shield layer 500 may be in direct contact with the first upper surface 211a of the first semiconductor chip 210. The first air path 610 may be provided in the first hole H1 and on the first portion 510 of the shield layer 500. Like in FIG. 9A, the first portions 510 of the shield layer 500 may be provided in a plurality, but are not limited thereto. When the semiconductor package 11 operates, at least a portion of the heat generated in the first semiconductor chip 210 may be rapidly dissipated outside through the first portion 510 of the shield layer 500.

The second portions 520 of the shield layer 500 may cover sidewalls and bottom surfaces of the second holes H2. The second portions 520 of the shield layer 500 may be in direct contact with the upper surface of the overhang portion of the heat-dissipating structure 300. The second air paths 620 may be provided in the second holes H2 and on the second portions 520 of the shield layer 500. When the semiconductor package 11 operates, another portion of the heat generated in the first semiconductor chip 210 may be transferred to the second portions 520 of the shield layer 500 through the first portion 510 of the shield layer 500 and the heat-dissipating structure 300. Due to distribution in paths through which the heat of the first semiconductor chip 210 are dissipated, the thermal properties of the semiconductor package 11 may be improved.

The second semiconductor chip 220 may be provided between the first portions 510 and the second portions 520 of the shield layer 500. For example, the first portions 510 of the shield layer 500 may be provided at a side of the second semiconductor chip 220, and at least some of the second portions 520 of the shield layer 500 may be provided at another side of the second semiconductor chip 220. EMI of the second semiconductor chip 220 may be shielded by the first portions 510 and the at least some of the second portions 520 of the shield layer 500. Accordingly, the reliability and electrical properties of the semiconductor package 11 may be improved.

The ground voltage may be applied to the heat-dissipating structure 300 through the ground pattern 130G and the shield layer 500. The heat-dissipating structure 300 may be arranged between the first semiconductor chip 210 and the second semiconductor chip 220 and shield EMI between the first semiconductor chip 210 and the second semiconductor chip 220.

Unlike in the illustration, the semiconductor package 11 may include the plurality of second semiconductor chips 220, and the second semiconductor chips 220 may be horizontally spaced apart from one another.

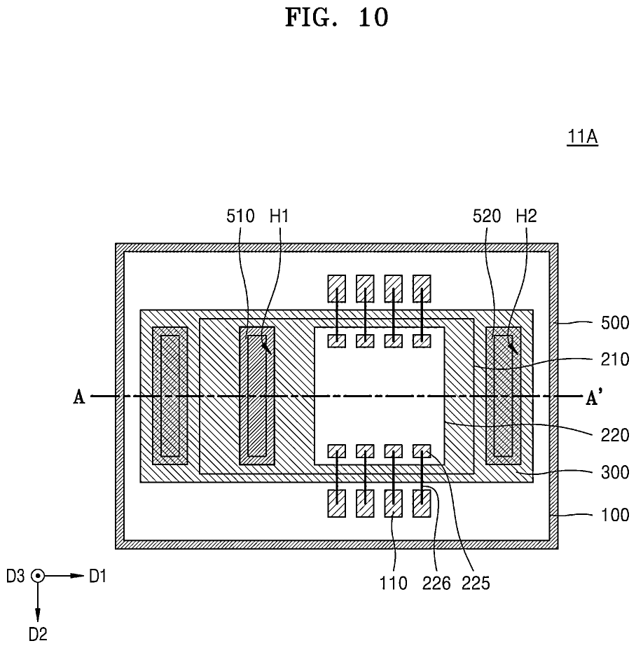

FIG. 10 is a plan view of a semiconductor package 11A according to embodiments. A cross-section taken along line A-A′ in FIG. 10 may be substantially identical to FIG. 9B. Hereinafter, FIG. 10 will be described in conjunction with FIG. 9C.

Referring to FIG. 10, the semiconductor package 11A may include the substrate 100, the first semiconductor chip 210, the heat-dissipating structure 300, the second semiconductor chip 220, the molding film 400, and the shield layer 500 as described with reference to the embodiments in FIGS. 9A to 9C. However, in a plan view, the first hole H1 may extend in the second direction D2. For example, the first hole H1 may have a bar shape or a rectangular shape extending in the second direction D2. As another example, the first hole H1 may have a square shape or a rectangular shape rounded at corners.

In a plan view, each of the second holes H2 may extend in the second direction D2. The second holes H2 may have a bar shape or a rectangular shape. As another example, the first hole H1 may have a square shape or a rectangular shape rounded at corners.

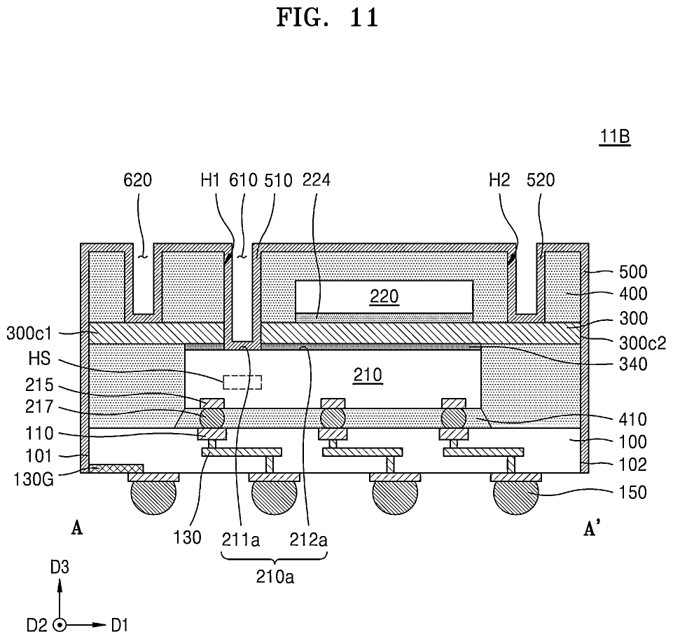

FIG. 11 is a cross-sectional view of a semiconductor package 11B according to embodiments, and corresponds to a cross-section of the semiconductor package 11 shown in FIG. 9A, taken along line A-A′.

Referring to FIG. 11, the semiconductor package 11B may include the substrate 100, the first semiconductor chip 210, the heat-dissipating structure 300, the second semiconductor chip 220, the molding film 400, and the shield layer 500.

The heat-dissipating structure 300 may have the outer sidewall 300c1 and the second outer sidewall 300c2 facing each other. Unlike in FIG. 9A, the first outer sidewall 300c1 of the heat-dissipating structure 300 may be vertically aligned or coplanar with the first side surface 101 of the substrate 100. The second outer sidewall 300c2 of the heat-dissipating structure 300 may be vertically aligned or coplanar with the second side surface 102 of the substrate 100. The molding film 400 may be spaced apart from the first outer sidewall 300c1 and the second outer sidewall 300c2 of the heat-dissipating structure 300. The shield layer 500 may cover the first outer sidewall 300c1 and the second outer sidewall 300c2 of the heat-dissipating structure 300. Therefore, each of the first outer sidewall 300c1 and the second outer sidewall 300c2 of the heat-dissipating structure 300 may be in direct contact with the shield layer 500. Unlike in FIG. 11, at least one of the first outer sidewall 300c1 and the second outer sidewall 300c2 of the heat-dissipating structure 300 may be spaced apart from the shield layer 500, and the molding film 400 may cover at least one of the first outer sidewall 300c1 and the second outer sidewall 300c2 of the heat-dissipating structure 300.

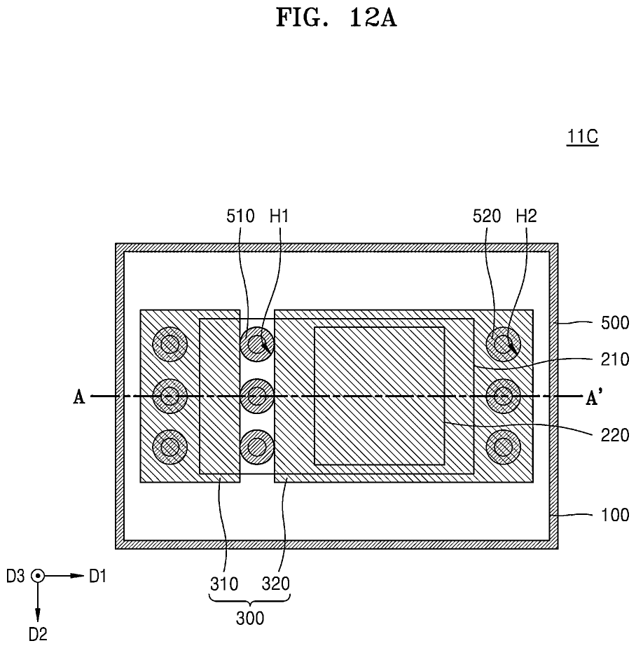

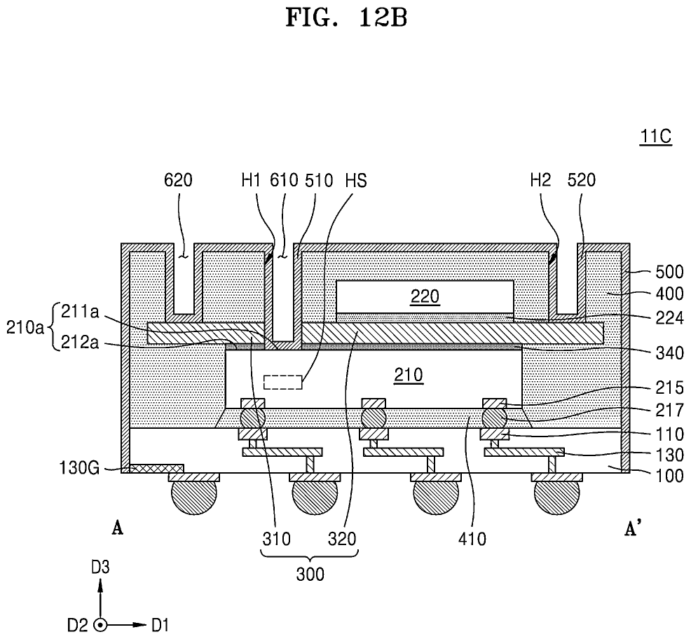

FIG. 12A is a plan view of a semiconductor package 11C according to embodiments. FIG. 12B is a cross-sectional view of the semiconductor package 11C shown in FIG. 12A, taken along a line A-A′. Hereinafter, same descriptions may be omitted in the interest of brevity.

Referring to FIGS. 12A and 12B, the semiconductor package 11C may include the substrate 100, the first semiconductor chip 210, the heat-dissipating structure 300, the second semiconductor chip 220, the molding film 400, and the shield layer 500. The heat-dissipating structure 300 may include the first heat-dissipating structure 310 and the second heat-dissipating structure 320 horizontally spaced apart from each other. The first hole H1 may be provided between the first heat-dissipating structure 310 and the second heat-dissipating structure 320. The first portion 510 of the shield layer 500 may contact the sidewall of the first heat-dissipating structure 310, the sidewall of the second heat-dissipating structure 320, and the first upper surface 211a of the first semiconductor chip 210.

Embodiments may be combined with each other. Among the embodiment of the semiconductor package 10 with reference to FIGS. 1A to IC, the embodiment of the shield layer 500 with reference to FIGS. 1D and 1E, the embodiment of the shield layer 500 with reference to FIGS. 4A and 4B, the embodiment of the semiconductor package 10A with reference to FIG. 5, the embodiment of the semiconductor package 10B with reference to FIG. 6, the embodiment of the semiconductor package 10C with reference to FIGS. 7A and 7B, the embodiment of the semiconductor package 10D with reference to FIG. 8, the embodiment of the semiconductor package 11 with reference to FIGS. 9A to 9C, the embodiment of the semiconductor package 11B with reference to FIG. 11, the embodiment of the semiconductor package 11C with reference to FIGS. 12A and 12B, at least two embodiments may be combined with each other.

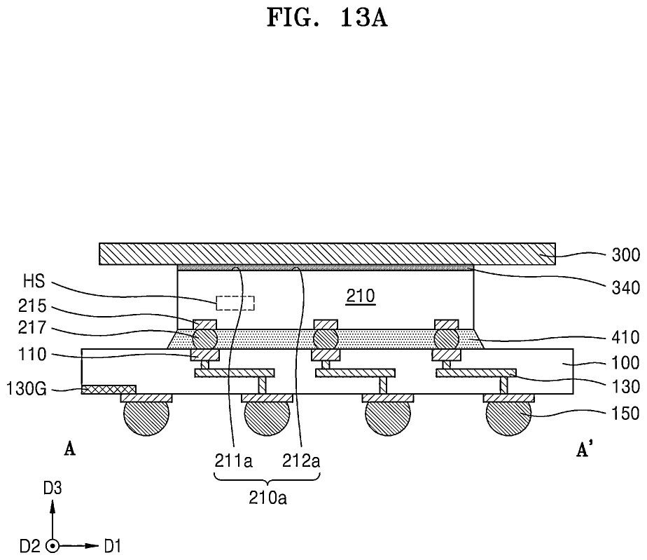

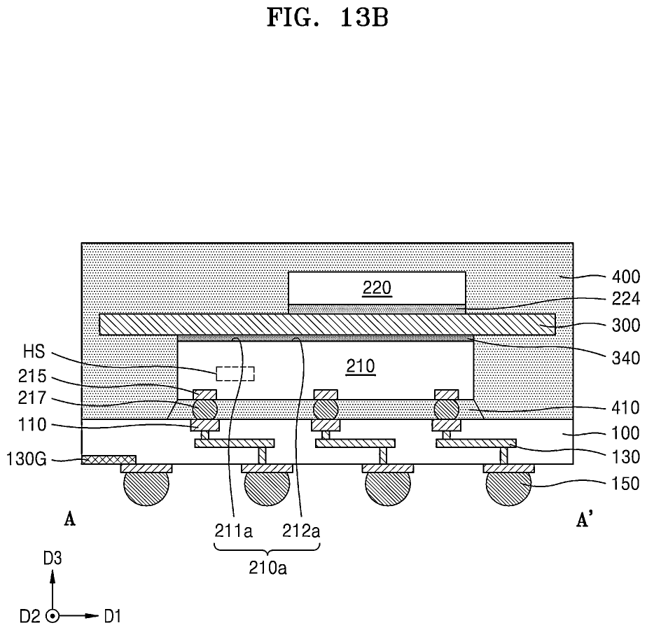

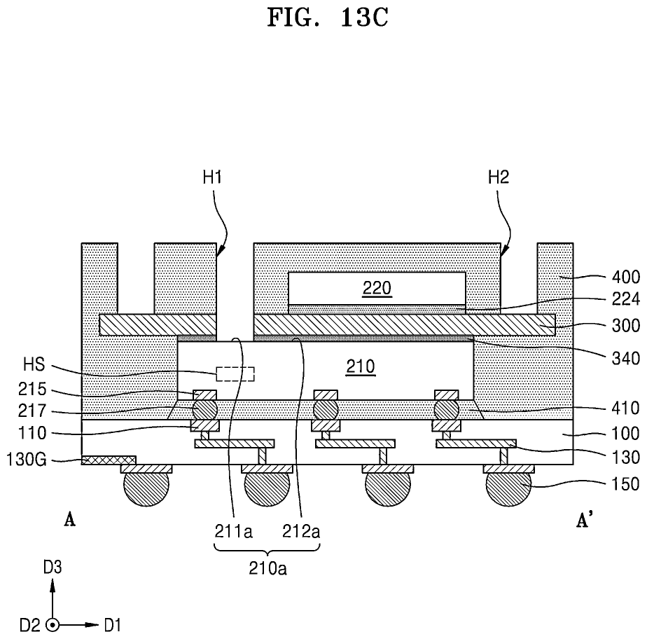

FIGS. 13A to 13C are diagrams for describing a process of manufacturing a semiconductor package according to embodiments, and correspond to cross-sections taken along line A-A′ in FIG. 9A. FIGS. 13A to 13C will be described in conjunction with FIGS. 9A and 9B.

Referring to FIG. 13A, the first semiconductor chip 210 may be mounted on the substrate 100 by using the bumps 217. The underfill film 410 may be formed between the substrate 100 and the first semiconductor chip 210. The heat-dissipating structure 300 may be arranged on the first semiconductor chip 210. The adhesive layer 340 may be formed between the heat-dissipating structure 300 and the first semiconductor chip 210 to attach the heat-dissipating structure 300 to the first semiconductor chip 210.

Referring to FIG. 13B, the second semiconductor chip 220 may be attached onto the heat-dissipating structure 300 by using the chip adhesion film 224. The first bonding wires 226 as described above in the embodiment shown in FIG. 9B may be formed on the second semiconductor chip 220. The second semiconductor chip 220 may contact the upper substrate pads 110 through the first bonding wires 226.

The molding film 400 may be formed on the upper surface of the substrate 100 and cover at least portions of the first semiconductor chip 210, the heat-dissipating structure 300, and the second semiconductor chip 220. As the recessed portion 380 is open toward the sidewall and the other sidewall of the heat-dissipating structure 300, the molding film 400 may be introduced into the recessed portion 380 and may cover the first semiconductor chip 210. The molding film 400 may fill the recessed portion 380. The upper surface of the molding film 400 may be substantially flat.

Referring to FIG. 13C, the first hole H1 and the second holes H2 may be formed in the molding film 400. Forming of the first hole H1 may be performed by, for example, a drilling process using laser. The first hole H1 may penetrate the molding film 400, the heat-dissipating structure 300, and the adhesive layer 340 and expose the first upper surface 211a of the first semiconductor chip 210. The forming of the first hole H1 may include removing a portion of the molding film 400, removing a portion of the heat-dissipating structure 300, and removing a portion of the adhesive layer 340. In the forming of the first hole H1, at least a portion of the first upper surface 211a of the first semiconductor chip 210 may be further removed. In this case, as described with reference to the embodiment shown in FIG. 3A, the first upper surface 211a of the first semiconductor chip 210 may be provided at a level lower than the level of the second upper surface 212a.

Forming of the second hole H2 may be performed through, for example, a drilling process using laser. The second holes H2 may penetrate the molding film 400. The forming of the second holes H2 may be performed until the upper surface of the heat-dissipating structure 300 is exposed. In the forming of the second holes H2, at least a portion of the upper surface of the heat-dissipating structure 300 may be further removed. In this case, as described with reference to the embodiment shown in FIG. 3B, the first upper surface 301a of the heat-dissipating structure 300 may be provided at a level lower than the level of the second upper surface 302a.

Referring again to FIG. 9C, the shield layer 500 may be formed on the upper surface of the molding film 400, the side surfaces of the molding film 400, the side surfaces of the substrate 100, the sidewalls and bottom surface of the first hole H1, and the sidewalls and bottom surfaces of the second holes H2. The shield layer 500 may contact the ground pattern 130G.

For example, the forming of the shield layer 500 may be performed through a spray coating process using a metal paste. For example, the metal paste may include an Ag paste.

As another example, the forming of the shield layer 500 may be performed through a deposition process or a sputtering process. The deposition process may include physical vapor deposition. For example, the forming of the shield layer 500 may include forming the first metal layer 501 (see FIGS. 4A and 4B) through a deposition process or a sputtering process, forming the second metal layer 502 (see FIGS. 4A and 4B) on the first metal layer 501 through a deposition process or a sputtering process, and forming the third metal layer 503 (see FIGS. 4A and 4B) on the second metal layer 502 through a deposition process or a sputtering process. In this case, the shield layer 500 may include the first metal layer 501, the second metal layer 502, and the third metal layer 503 described with reference to the embodiment shown in FIGS. 4A and 4B. Differently, the shield layer 500 may include a single metal layer. The manufacturing of the semiconductor package 11 may be complete according to the embodiments.

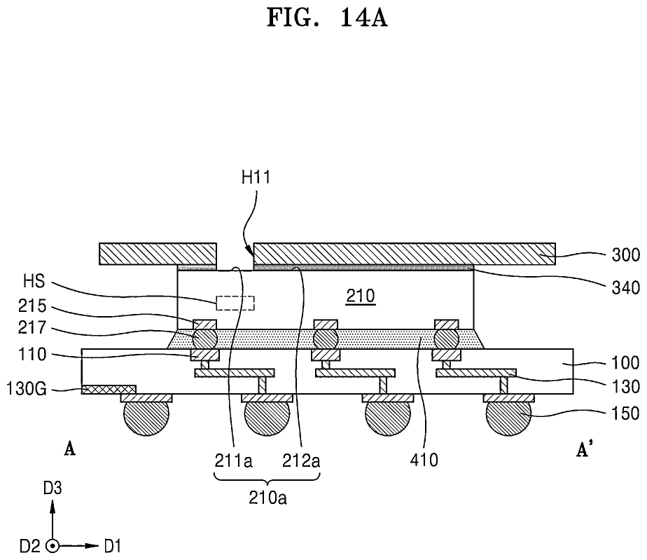

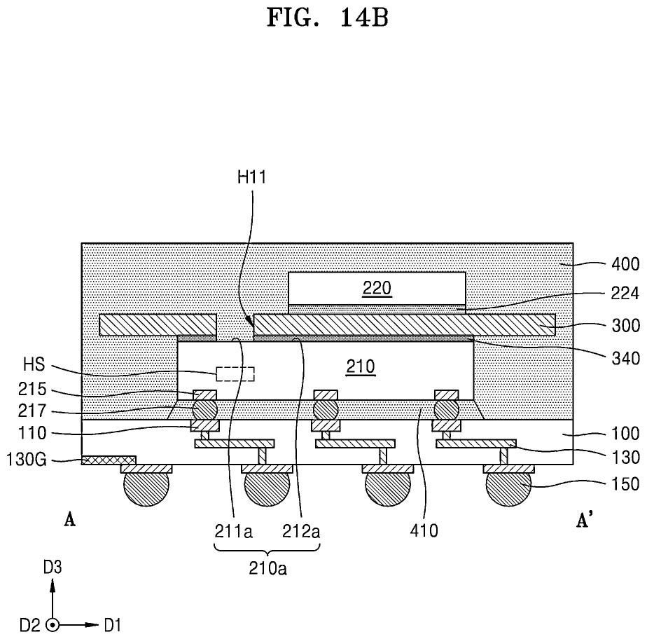

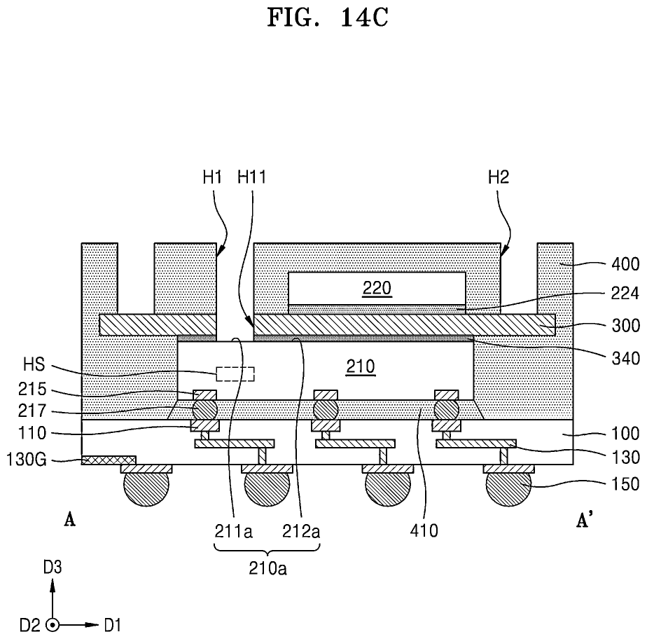

FIGS. 14A to 14C are diagrams for describing a process of manufacturing a semiconductor package according to embodiments, and correspond to cross-sections taken along line A-A′ shown in FIG. 9A. FIGS. 14A to 14C will be described in conjunction with FIGS. 9A and 9B.

Referring to FIG. 14A, the first semiconductor chip 210 may be mounted on the substrate 100 by using the bumps 217. The underfill film 410 may be further formed between the substrate 100 and the first semiconductor chip 210.

The heat-dissipating structure 300 having a first preliminary hole H11 may be prepared. The first preliminary hole H11 may penetrate the upper surface and the lower surface of the heat-dissipating structure 300. The heat-dissipating structure 300 may be arranged on the second upper surface 212a of the first semiconductor chip 210 such that the first preliminary hole H11 of the heat-dissipating structure 300 vertically overlaps the heat source HS of the first semiconductor chip 210. As the adhesive layer 340 is formed between the first semiconductor chip 210 and the heat-dissipating structure 300, the heat-dissipating structure 300 may be attached to the first semiconductor chip 210.

Referring to FIG. 14B, the second semiconductor chip 220 may be attached onto the heat-dissipating structure 300 by using the chip adhesion film 224. The first bonding wires 226 as described above in the embodiment shown in FIG. 9B may be formed on the second semiconductor chip 220. The molding film 400 may be formed on the substrate 100 and cover at least portions of the first semiconductor chip 210, the heat-dissipating structure 300, and the second semiconductor chip 220. The molding film 400 may be further provided in the first preliminary hole H11.

Referring to FIG. 14C, the first hole H1 and the second holes H2 may be formed in the molding film 400. Forming of the first hole H1 may be performed by, for example, a drilling process using laser. The forming of the first hole H1 may include removing a portion of the molding film 400. A portion of the molding film 400 may include a portion of the molding film 400 in the first preliminary hole H11. As the heat-dissipating structure 300 has the first preliminary hole H11, removing a portion of the heat-dissipating structure 300 may be omitted from the forming of the first hole H1. Accordingly, the first hole H1 may be more easily and simply formed. The first hole H1 may be connected to the first preliminary hole H11. For example, the first preliminary hole H11 may correspond to a lower portion of the first hole H1.

Forming of the second holes H2 may be performed through a method substantially identical to the method described with reference to the embodiment shown in FIG. 13C. For example, the forming of the second hole H2 may be performed through, for example, a drilling process using laser.

Referring again to FIG. 9C, the shield layer 500 may be formed on the upper surface of the molding film 400, the side surfaces of the molding film 400, the side surfaces of the substrate 100, the sidewalls and bottom surface of the first hole H1, and the sidewalls and bottom surfaces of the second holes H2. For example, the forming of the shield layer 500 may be performed through a spray coating process using a metal paste. As another example, the forming of the shield layer 500 may be performed through a sputtering process or a deposition process as described with reference to the embodiment shown in FIG. 13C. The manufacturing of the semiconductor package 11 may be complete according to the embodiments.

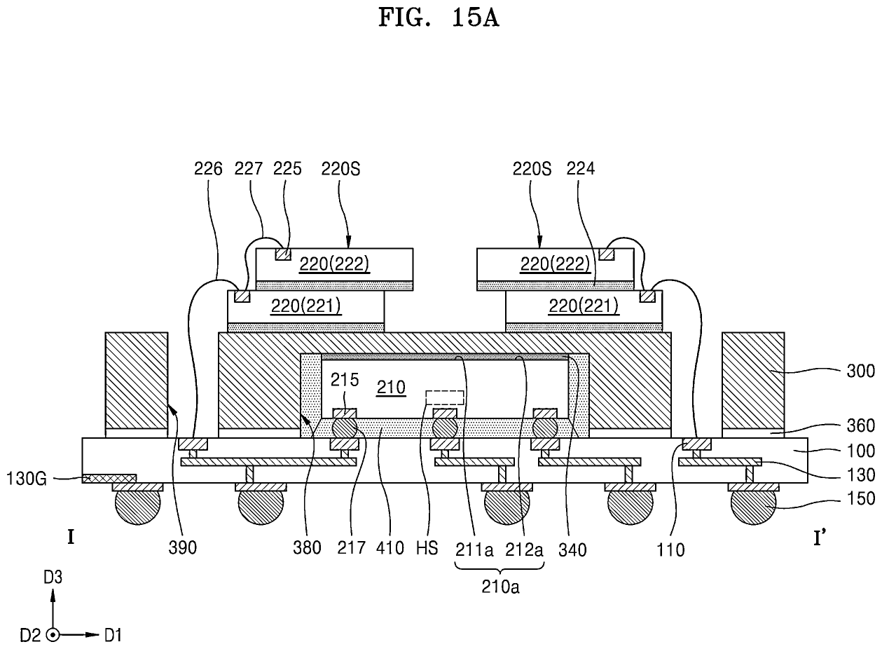

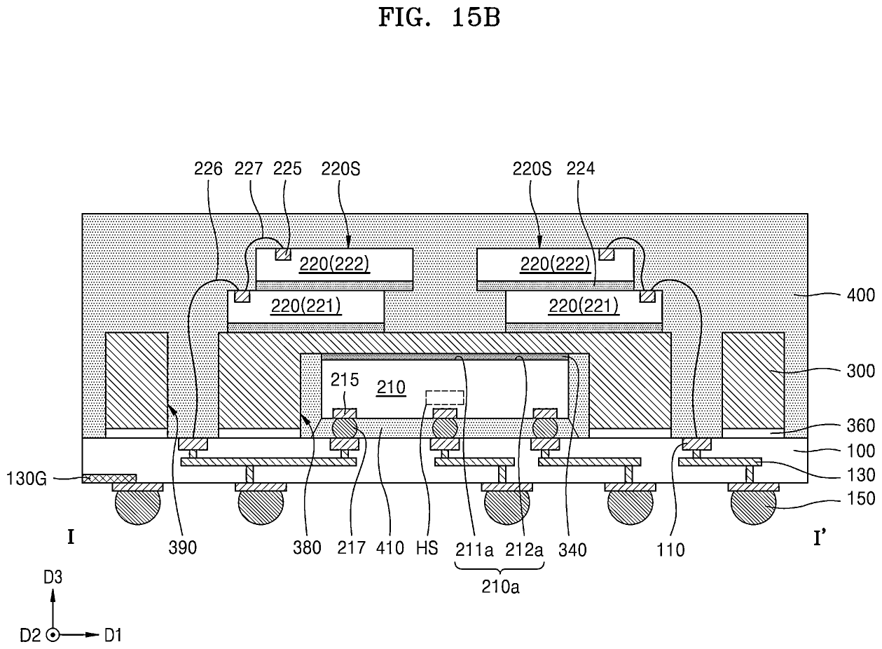

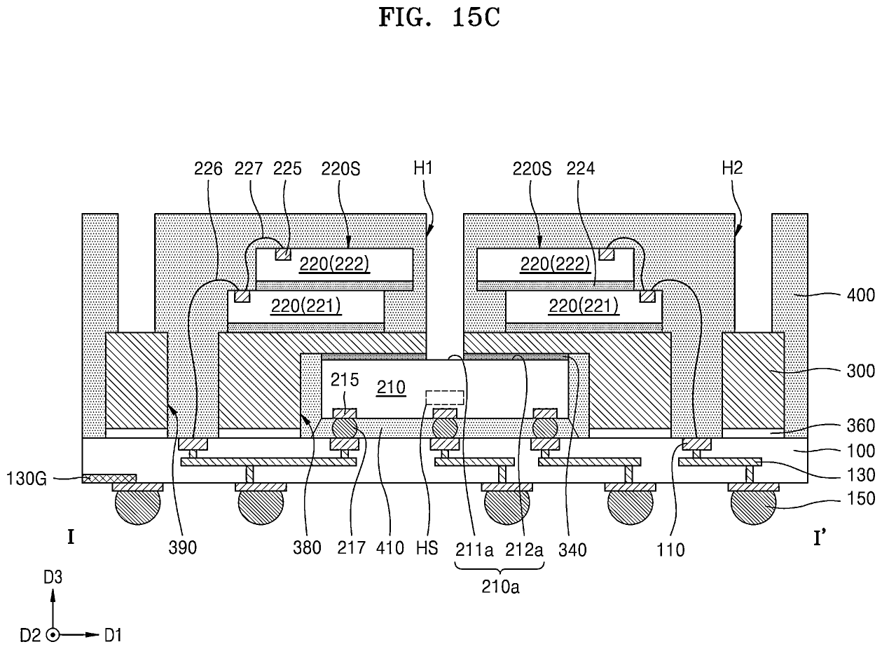

FIGS. 15A to 15C are diagrams for describing a process of manufacturing a semiconductor package according to embodiments, and correspond to cross-sections taken along line A-A′ shown in FIG. 1A. FIGS. 15A to 15C will be described in conjunction with FIGS. 1A and 1B.

Referring to FIG. 15A, the first semiconductor chip 210 may be mounted on the substrate 100 by using the bumps 217. The underfill film 410 may be further formed between the substrate 100 and the first semiconductor chip 210. The heat-dissipating structure 300 having the recessed portion 380 may be prepared. The heat-dissipating structure 300 may be arranged on the substrate 100 and the first semiconductor chip 210 such that the recessed portion 380 of the heat-dissipating structure 300 is provided on the first semiconductor chip 210. The adhesive layer 340 may be formed between the heat-dissipating structure 300 and the first semiconductor chip 210 to attach the heat-dissipating structure 300 to the first semiconductor chip 210.

The chip stacks 220S may be arranged on the heat-dissipating structure 300. The chip stacks 220S may include the second semiconductor chips 220 in a stack. The chip adhesion films 224 may be formed on the lower surfaces of the second semiconductor chips 220 for attachment of the second semiconductor chips 220 to the heat-dissipating structure 300. The first bonding wires 226 and the second bonding wires 227 may be formed on the second semiconductor chips 220 and may electrically connect the second semiconductor chips 220 to the substrate 100.

Referring to FIG. 15B, the molding film 400 may be formed on the substrate 100 and cover the first semiconductor chip 210, the heat-dissipating structure 300, and the second semiconductor chip 220. The upper surface of the molding film 400 may be substantially flat.

Referring to FIG. 15C, the first hole H1 and the second holes H2 may be formed in the molding film 400. The forming of the first hole H1 and the forming of the second holes H2 may be performed through the method described with reference to the embodiment shown in FIG. 13C. In the forming of the first hole H1, at least a portion of the first upper surface 211a of the first semiconductor chip 210 may be further removed. In this case, as described with reference to the embodiment shown in FIG. 3A, the first upper surface 211a of the first semiconductor chip 210 may be provided at a level lower than the level of the second upper surface 212a. In the forming of the second holes H2, at least a portion of the upper surface of the heat-dissipating structure 300 may be further removed. In this case, as described with reference to the embodiment shown in FIG. 3B, the first upper surface 301a of the heat-dissipating structure 300 may be provided at a level lower than the level of the second upper surface 302a.

Unlike the descriptions with reference to FIGS. 15A to 15C, after the first semiconductor chip 210 is mounted on the first semiconductor chip 210, the heat-dissipating structure 300 having the recessed portion 380 and the first preliminary hole may be arranged on the first semiconductor chip 210 and the substrate 100. The heat-dissipating structure 300 may be arranged on the first semiconductor chip 210 such that the preliminary hole of the first heat-dissipating structure 310 exposes the first upper surface 211a of the first semiconductor chip 210. The adhesive layer 340 may be formed between the second upper surface 212a of the first semiconductor chip 210 and the heat-dissipating structure 300. Next, the chip stacks 220S may be arranged on the upper surface of the heat-dissipating structure 300. The molding film 400 may be formed on the substrate 100, may cover the first semiconductor chip 210, the heat-dissipating structure 300, and the second semiconductor chip 220, and may extend into the first preliminary hole. The first hole H1 and the second holes H2 may be formed in the molding film 400. The forming of the first hole H1 may include removing a portion of the molding film 400 through a drilling process using laser. The portion of the molding film 400 may include the portion of the molding film 400 in the first preliminary hole. The first hole H1 may be connected to the first preliminary hole, and the first preliminary hole may correspond to the lower portion of the first hole H1.

Referring again to FIG. 1C, the shield layer 500 may be formed on the upper surface of the molding film 400, the side surfaces of the molding film 400, the side surfaces of the substrate 100, the sidewalls and the bottom surface of the first hole H1, and the sidewalls and bottom surfaces of the second holes H2. For example, the forming of the shield layer 500 may be performed through a spray coating process using a metal paste. As another example, the forming of the shield layer 500 may be performed through a sputtering or deposition process. For example, the forming of the shield layer 500 may include forming the first metal layer 501, the second metal layer 502, and the third metal layer 503 described with reference to the embodiment shown in FIGS. 4A and 4B through a sputtering or deposition process. The manufacturing of the semiconductor package 10 may be complete according to the embodiments.

According to the inventive concept, the first portion of the shielding layer may extend into the molding film, the heat-dissipating structure, and the adhesive layer and contact the upper surface of the first semiconductor chip. Thermal conductivity of the shield layer may be greater than thermal conductivity of the adhesive layer. Accordingly, heat dissipation properties of the first semiconductor chip may be further improved. The second portion of the shield layer may extend into the molding film and contact the upper surface of the heat-dissipating structure. The heat generated in the first semiconductor chip may be dissipated outside through the heat-dissipating structure and the second portion of the shield layer. The semiconductor package may have improved thermal properties.

The second semiconductor chip may be provided between the first portion and the second portion of the shield layer. EMI of the second semiconductor chip may be improved by the shield layer. The ground voltage may be applied to the heat-dissipating structure through the shield layer. The heat-dissipating structure may shield EMI between the first semiconductor chip and the second semiconductor chip. Electrical properties and reliability of the semiconductor package may be improved.

While the inventive concept has been particularly shown and described with reference to example embodiments thereof, it will be understood that various changes in form and details may be made therein without departing from the spirit and scope of the following claims.

What is claimed is:

1. A semiconductor package comprising:
a substrate;
a first semiconductor chip on the substrate;
a heat-dissipating structure on the first semiconductor chip;
an adhesive layer between the first semiconductor chip and the heat-dissipating structure;
a second semiconductor chip on the heat-dissipating structure;
a molding film on the substrate and covering at least portions of the first semiconductor chip, the heat-dissipating structure, and the second semiconductor chip; and
a shield layer on an upper surface and sidewalls of the molding film,
wherein the shield layer comprises a first portion extending into a first hole and contacting an upper surface of the first semiconductor chip, and the first hole penetrates the molding film, the heat-dissipating structure, and the adhesive layer.

2. The semiconductor package of claim 1, wherein a thermal conductivity of the shield layer is greater than a thermal conductivity of the adhesive layer.

3. The semiconductor package of claim 1, wherein the first portion of the shield layer contacts an inner sidewall of the heat-dissipating structure.

4. The semiconductor package of claim 1, wherein a first air path is provided in the first hole and on the first portion of the shield layer, and the first air path is connected to an external space.

5. The semiconductor package of claim 1, further comprising a bonding wire on an upper surface of the second semiconductor chip and electrically connected to the second semiconductor chip and the substrate,
wherein the heat-dissipating structure has a trench between an upper surface and a lower surface of the heat-dissipating structure, and
the bonding wire is in the trench.

6. The semiconductor package of claim 1, wherein the shield layer further comprises:
a first metal layer covering the molding film, inner sidewalls of the heat-dissipating structure, inner sidewalls of the adhesive layer, and a portion of an upper surface of the first semiconductor chip;
a second metal layer on the first metal layer and comprising a metal that is different from the metal of the first metal layer; and
a third metal layer on the second metal layer and comprising a metal that is identical to a metal of the first metal layer.

7. The semiconductor package of claim 6, wherein the second metal layer has a thermal conductivity that is higher than thermal conductivities of the first metal layer and the third metal layer, and
a thickness of the second metal layer is greater than a thickness of the first metal layer and a thickness of the third metal layer.

8. The semiconductor package of claim 1, wherein the heat-dissipating structure comprises:
an overlapping portion on an upper surface of the first semiconductor chip; and
an overhang portion horizontally spaced apart from the first semiconductor chip,
wherein the shield layer further comprises a second portion that penetrates the molding film and contacts an upper surface of the overhang portion of the heat-dissipating structure.

9. The semiconductor package of claim 1, wherein a first outer sidewall of the heat-dissipating structure is vertically aligned with a first side surface of the substrate, and
the shield layer contacts the first outer sidewall of the heat-dissipating structure.

10. A semiconductor package comprising:
a substrate;
a first semiconductor chip on the substrate and having a first upper surface and a second upper surface;
a heat-dissipating structure on the first semiconductor chip;
an adhesive layer between the second upper surface of the first semiconductor chip and the heat-dissipating structure;
a second semiconductor chip on an upper surface of the heat-dissipating structure;
a molding film on the heat-dissipating structure and the second semiconductor chip; and
a metal layer on an upper surface and sidewalls of the molding film,
wherein the metal layer comprises:
a first portion extending into a first hole penetrating the molding film, the heat-dissipating structure, and the adhesive layer, the first portion being in direct contact with the first upper surface of the first semiconductor chip; and
a second portion extending into a second hole penetrating the molding film, the second portion being in direct contact with an upper surface of the heat-dissipating structure.

11. The semiconductor package of claim 10, wherein the second portion of the metal layer is spaced apart from the first semiconductor chip.

12. The semiconductor package of claim 10, wherein the first upper surface of the first semiconductor chip is provided at a vertical level lower than a vertical level of the second upper surface of the first semiconductor chip.

13. The semiconductor package of claim 10, wherein
a first air path is provided in the first hole and on the first portion of the metal layer,
a second air path is provided in the second hole and on the second portion of the metal layer, and
the first air path and the second air path are connected to an external space.

14. The semiconductor package of claim 10, wherein
the first hole comprises a plurality of first holes spaced apart from one another and each having a circular or elliptical shape, and
the second hole comprises a plurality of second holes spaced apart from one another and each having a circular or elliptical shape.

15. The semiconductor package of claim 10, wherein the second semiconductor chip is between the first portion of the metal layer and the second portion of the metal layer.

16. The semiconductor package of claim 10,
wherein the substrate comprises a ground pattern,
the metal layer is electrically connected to the ground pattern, and
a ground voltage is configured to be applied to the heat-dissipating structure through the ground pattern and the metal layer.

17. A semiconductor package comprising:
a substrate comprising a ground pattern;
solder ball terminals on a lower surface of the substrate;
a first semiconductor chip on an upper surface of the substrate;
bumps between the substrate and the first semiconductor chip and contacting the substrate and the first semiconductor chip;
a heat-dissipating structure on an upper surface of the first semiconductor chip and having a width that is greater than a width of the first semiconductor chip;
an adhesive layer between the first semiconductor chip and the heat-dissipating structure;
a second semiconductor chip on the heat-dissipating structure;
bonding wires on the second semiconductor chip and electrically connected to the second semiconductor chip and the substrate;
a molding film on the upper surface of the substrate and on side surfaces of the first semiconductor chip, the heat-dissipating structure, the second semiconductor chip, and the bonding wires; and
a shield layer on an upper surface and side surfaces of the molding film, the shield layer extending onto side surfaces of the substrate and electrically connected to the ground pattern,
wherein the shield layer further comprises:
a first portion in a first hole penetrating the molding film, the heat-dissipating structure, and the adhesive layer; and
a second portion in a second hole penetrating the molding film,
wherein the first portion of the shield layer contacts an upper surface of the first semiconductor chip, and
the second portion of the shield layer contacts an upper surface of the heat-dissipating structure and is spaced apart from the first semiconductor chip.

18. The semiconductor package of claim 17,
wherein the first portion of the shield layer is one of a plurality of the first portions of the shield layer,
the second portion of the shield layer is one of a plurality of the second portions of the shield layer, and
the plurality of first portions and the plurality of second portions of the shield layer surround the second semiconductor chip.

19. The semiconductor package of claim 18,
wherein the second semiconductor chip comprises a plurality of second semiconductor chips horizontally spaced apart from each other, and
the plurality of first portions of the shield layer are disposed between the plurality of second semiconductor chips.

20. The semiconductor package of claim 17, wherein a thickness of the adhesive layer is from about 10 μm to about 50 μm.
